(19) United States
(12) Patent Application Publication
(10) Pub. No.: US 2024/0061070 A1
(43) Pub. Date: Feb. 22, 2024

(54) Interference-Resistant Microwave Detection Method and Microwave Detection Device

(71) Applicant: Shenzhen Merrytek Technology Co.,Ltd., (US)

(72) Inventors: Gaodi ZOU, Shenzhen (CN); Xin ZOU, Shenzhen (CN); Yi SUN, Shenzhen (CN)

(21) Appl. No.: 18/284,190

(22) PCT Filed: Jun. 21, 2023
(86) PCT No.: PCT/CN2023/101682

§ 371 Date: Sep. 26, 2023

(30) Foreign Application Priority Data
Jul. 15, 2022 (CN) 202210836152X
Apr. 16, 2023 (CN) 2023104560904
Jun. 21, 2023 (WO) PCT/CN2023/101682

(51) Int. Cl. G01S 7/02; G01S 13/534; G01S 13/524; G01S 13/56

(52) U.S. Cl. CPC G01S 7/023; G01S 13/534; G01S 13/5244; G01S 13/56

(57) ABSTRACT

An anti-interference microwave detection method and microwave detection device, wherein the anti-interference microwave detection method can accurately eliminate the interference signal in the environment that have any frequency relationship with the local oscillator signal of the microwave detection device, including same frequency, adjacent frequency, and harmonic frequency, so that it is conducive to improve the feedback accuracy of the Doppler intermediate frequency signal for the detection of the motion of objects in the corresponding detection space, so that it is beneficial for achieving the combined detection of motion characteristics including human movement, micro-movement, breath and hear beat, the detection function of the microwave detection device is diversified and suitable for intelligent detection applications of multifunctional requirements.

### BACKGROUND OF THE PRESENT INVENTION

### Field of Invention

The present invention relates to the field of Doppler microwave detection, and more particularly to an interference-resistant microwave detection method and microwave detection device.

### Description of Related Arts

With the development of internet technology, the demand for accurate detection of environmental factors, especially for human presence, movement, and micro-motion characteristics, is increasing in artificial intelligence, smart home appliance, and intelligent security technology. Only by obtaining real-time and stable detection results, accurate judgment basis can be provided for intelligent terminal devices. Among them, radio technology, especially microwave detection technology based on the principle of Doppler effect, has unique advantages in behavior detection and existence detection technology as it can function as an important hub linking people with thing and linking different things. The microwave detection technology, which can detect active objects without violating human privacy by detecting human action characteristics, movement characteristics, and micro-motion characteristics, and even human heartbeat and respiratory characteristic information, has a wide range of application prospects.

Referring to FIG. 1, the circuit structure principle of the Doppler microwave detection device is illustrated. The Doppler microwave detection device comprises an antenna body 10P for transmitting and/or receiving microwaves. The antenna body 10P transmits a detection beam corresponding to the frequency of the local oscillator signal fed by a mixer 20P to form a corresponding detection space, and receives a reflected wave formed by the detection beam reflected by an object in the detection space to form a feedback signal generated by the reflected wave. The mixer 20P receives the feedback signal and outputs a Doppler intermediate frequency signal corresponding to the frequency difference between the local oscillator signal and the feedback signal by mixing and detecting. Based on the principle of Doppler effect, the amplitude fluctuation of the Doppler intermediate frequency signal theoretically corresponds to the movement of the object in the detection space. On one hand, environmental interference signals that can be received by the antenna body 10P will be superimposed on the Doppler intermediate frequency signal to form a first type of interference signal in the Doppler intermediate frequency signal. On the other hand, signals in the environmental interference signals that have the same frequency, adjacent frequency, or harmonic frequency relationships with the local oscillator signal will also be superimposed on the feedback signal and participate in the mixing and detecting process to form a second type of interference signal mixed with the effective signal in the Doppler intermediate frequency signal.

For the first type of interference signal, currently, filtering is mainly used to filter out the corresponding frequency range of the first type of interference signal that is superimposed on the Doppler intermediate frequency signal, or the frequency range of the antenna body 10P for receiving environmental interference signals is narrowed by narrowing the bandwidth of the antenna body 10P. However, based on the working principle of filtering, on one hand, the filtering process will filter out the effective signal of the corresponding frequency in the Doppler intermediate frequency signal and destroy the integrity of the Doppler intermediate frequency signal output by the filter; on the other hand, it will also form an integral processing of the effective signal of the corresponding frequency in the Doppler intermediate frequency signal, making it difficult to ensure the corresponding relationship between the output parameters and physical meaning of the Doppler intermediate frequency signal. In addition, refer to FIG. 2 of the drawings of the present application. In the state where there is no object activity in the detection space, when the Doppler intermediate frequency signal output by the mixer 20P is filtered by the corresponding filtering circuit, the Doppler intermediate frequency signals sampled at the input and output terminals of the filtering circuit are compared in an up-down arrangement. Currently, the filtering of the Doppler intermediate frequency signal essentially involves integrating and smoothing the signals in the corresponding frequency range of the Doppler intermediate frequency signal, which cannot achieve true elimination processing. Especially when the signal intensity in this frequency range is high, multiple filtering processes are usually required. Therefore, based on the aforementioned filtering method, the above mentioned two aspects of influences will be generated several times on the Doppler intermediate frequency signal output after the filtering process, the accuracy of the feedback of the filtered Doppler intermediate frequency signal to the movement of objects in the detection space is difficult to guarantee, especially for the feedback accuracy of micro-movements in the detection space.

For the second type of interference signal, even in the state of knowing the frequency range of the environmental interference signal generated by the interference source, due to the uncertainty of the frequency change rate of the interference source, when the Doppler intermediate frequency signal corresponds to the frequency difference between the local oscillator signal and the feedback signal (superimposed with environmental interference signal), when the corresponding filtering circuit is used to filter the Doppler intermediate frequency signal output by the mixer 20P, on one hand, the accuracy and stability of the correspondence between the parameter design of the filtering circuit and the frequency range of the second type of interference signal cannot be guaranteed, so that the corresponding second type of interference signal is difficult to be separated and filtered from the Doppler intermediate frequency signal by filtering; on the other hand, the parameter design of the filtering circuit does not correspond to the frequency range of the first type of interference signal, so that mutual influence is east to take place, and may result in multiple filtering processing of the Doppler intermediate frequency signal. In addition, based on the aforementioned filtering method, the two influential aspects of the Doppler intermediate frequency signal output by the filtering will also cause the accuracy of the feedback of the filtered output Doppler intermediate frequency signal to the motion of objects in the detection space difficult to guarantee. Therefore, for the suppression of the second type of interference signal, it is currently considered more reasonable to reduce the probability that the local oscillator signal will form any frequency relationship of the same frequency, adjacent frequency, or harmonic frequency with the environmental interference signal for a long time through the method of jumping/changing frequency. However, this method can only reduce the probability of the existence of the second type of interference signal in the Doppler intermediate frequency signal for a long time, and still cannot separate and filter out the second type of interference signal from the Doppler intermediate frequency signal.

In summary, using filtering to simultaneously filter the first and second types of interference signals in the Doppler intermediate frequency signal essentially selects the signals in the corresponding frequency range of the Doppler intermediate frequency signal for integration and smoothing, which cannot achieve true elimination and usually requires multiple filtering processes. In addition, regarding the second type of interference signal, the parameter design of the filtering circuit is not stable and accurate in correspondence with the frequency range of the second type of interference signal, and there is no corresponding relationship with the frequency range of the first type of interference signal, which can easily affect each other and require multiple filtering processes on the Doppler intermediate frequency signal. Based on the aforementioned multiple impacts of the filtering method by the two aspects of influences on the Doppler intermediate frequency signal, the accuracy of the feedback of the filtering output Doppler intermediate frequency signal to the movement of objects in the detection space cannot be guaranteed.

### SUMMARY OF THE PRESENT INVENTION

An object of the present invention is to provide an anti-interference microwave detection method and microwave detection device, wherein the anti-interference microwave detection method can accurately eliminate the second type of interference signal formed in the corresponding Doppler intermediate frequency signal by interference signals in the environment that have any frequency relationship with the local oscillator signal of the microwave detection device, comprising same frequency, adjacent frequency, and harmonic frequency, so that it is conducive to improve the feedback accuracy of the Doppler intermediate frequency signal for the detection of the motion of objects in the corresponding detection space.

Another object of the present invention is to provide an anti-interference microwave detection method and microwave detection device, wherein by forming a differential signal form of the Doppler intermediate frequency signal, based on the formation process of the first type of interference signal and the second type of interference signal, the first type of interference signal and the second type of interference signal correspond to the common mode interference and differential mode interference respectively existing in the differential signal form of the Doppler intermediate frequency signal, and can be distinguished from each other. Then, the first type of interference signal and the second type of interference signal in the differential signal form of the Doppler intermediate frequency signal can be suppressed or eliminated based on different signal processing methods without affecting each other. This is conducive to ensuring the integrity of the Doppler intermediate frequency signal and the accuracy of the feedback of the detection of the motion of objects in the corresponding detection space, and is correspondingly conducive to realize combined detection of motion characteristics comprising human movement, micro-movement, breathing, and heartbeat, and the detection function of the corresponding microwave detection device is diversified and suitable for intelligent detection applications with multifunctional requirements.

Another object of the present invention is to provide an anti-interference microwave detection method and microwave detection device, wherein in the state where the second type of interference signal is loaded as common mode interference in the differential signal form of the Doppler intermediate frequency signal, the second type of interference signal in the corresponding frequency range of the Doppler intermediate frequency signal is eliminated by cancellation in a way that is conducive to avoiding the use of multiple filtering methods, thus ensuring the integrity of the Doppler intermediate frequency signal and the corresponding relationship between the parameters of the Doppler intermediate frequency signal and the physical information of the motions of the objects, and improving the feedback accuracy of the Doppler intermediate frequency signal for the detection of the motion of objects in the corresponding detection space.

Another object of the present invention is to provide an anti-interference microwave detection method and microwave detection device, wherein in practical applications, the environmental interference signal that has the same frequency, adjacent frequency, or harmonic frequency relationship with the local oscillator signal of the microwave detection device is mainly wireless communication signal. Through exploration of the principle of wireless communication and actual testing of different products, it is found that the frequency change rate of the signal in wireless communication signal based on frequency modulation, which expresses communication information through frequency change, is much higher than the frequency change rate of the feedback signal corresponding to the normal moving object based on the principle of Doppler effect. The corresponding second type of interference signal exists in the form of high-frequency spikes in the differential signal form of the Doppler intermediate frequency signal, so it can accurately eliminate the second type of interference signal in the corresponding frequency range in the Doppler intermediate frequency signal of the differential signal shape based on selective cancellation, thus ensuring the microwave detection device's ability to resist communication interference, which has significant practical value and commercial significance.

Another object of the present invention is to provide an anti-interference microwave detection method and microwave detection device, wherein the anti-interference microwave detection method can avoid the use of multiple filtering methods and the signal delay caused by filtering processing, and can suppress or eliminate the first type of interference signal and the second type of interference signal in the differential signal form of the Doppler intermediate frequency signal, so as to ensure the immediacy of the Doppler intermediate frequency signal and is beneficial to achieve real-time detection of actions comprising human breathing and heartbeat.

Another object of the present invention is to provide an anti-interference microwave detection method and microwave detection device, wherein in the application scenarios of multiple microwave detection devices, the environmental interference signals with the same frequency relationship as the local oscillator signal of the microwave detection device may also be signals emitted by other microwave detection devices with the same frequency, forming first and second types of interference signals in the differential signal form of the multi-Doppler intermediate frequency signal in the form of spikes. Before the microwave detection device eliminates the second type of interference signal in the corresponding frequency range in a selective cancellation manner, it can optionally connect a ground capacitor with the same parameter setting at the two poles of the differential signal form of the multi-Doppler intermediate frequency signal to suppress the first and second types of interference signals formed in the form of spikes by the same frequency interference in the differential signal form of the multi-Doppler intermediate frequency signal, so as to ensure the anti-interference ability of the microwave detection device in the application scenarios of multiple microwave detection devices.

Another object of the present invention is to provide an anti-interference microwave detection method and microwave detection device, wherein the first type of interference signal exists as a common mode interference in the differential signal form of the Doppler intermediate frequency signal, so that it is suitable to suppress the first type of interference signal in the differential signal form of the Doppler intermediate frequency signal by differential amplification of the differential signal form of the Doppler intermediate frequency signal, while amplifying the differential signal form of the Doppler intermediate frequency signal, thereby suppressing the interference to the Doppler intermediate frequency signal by the first type of interference signal formed by environmental interference signals that can be received by the microwave detection device, thereby improving the feedback accuracy of the Doppler intermediate frequency signal corresponding to the motion of objects in the corresponding detection space.

Another object of the present invention is to provide an anti-interference microwave detection method and microwave detection device, wherein the first type of interference signal exists as common-mode interference in the differential signal form of the Doppler intermediate frequency signal, and is therefore suitable for suppressing and eliminating common-mode interference in the process of converting the differential signal form of the Doppler intermediate frequency signal to the Doppler intermediate frequency signal in the single-ended signal form, and suppressing and eliminating the interference of the first type of interference signal formed by environmental interference signals that can be received by the microwave detection device on the Doppler intermediate frequency signal through the identification and operation of data by converting the differential signal form of the Doppler intermediate frequency signal to the Doppler intermediate frequency signal in the single-ended signal form, thereby ensuring the feedback accuracy of the Doppler intermediate frequency signal on the movement of the object.

Another object of the present invention is to provide an anti-interference microwave detection method and microwave detection device, wherein by forming a differential signal form of the Doppler intermediate frequency signal, the radiation of the differential signal form of the Doppler intermediate frequency signal can cancel each other out, so that the interference of the Doppler intermediate frequency signal on the environment and corresponding circuits can be suppressed, which is beneficial to improve the anti-interference performance of the microwave detection device.

Another object of the present invention is to provide an anti-interference microwave detection method and microwave detection device, wherein by forming a differential signal form of the Doppler intermediate frequency signal, if the first type of interference signal corresponds to the common mode interference existing in the differential signal form of the Doppler intermediate frequency signal, then the differential amplification processing of the differential signal form of the Doppler intermediate frequency signal and/or the conversion of the single-end signal form of the Doppler intermediate frequency signal can achieve the amplification and anti-interference processing of the Doppler intermediate frequency signal in a state that ensures the integrity of the feedback of the motion of the object in the detection space, which is beneficial to obtain accurate and stable detection results of human activities comprising human movement, micro-movement, breathing, and heartbeat based on the Doppler intermediate frequency signal.

Another object of the present invention is to provide an anti-interference microwave detection method and microwave detection device, wherein in comparison with the filtering method, the differential amplification processing of the Doppler intermediate frequency signal's differential signal waveform and/or the conversion of the Doppler intermediate frequency signal to the single-ended signal waveform can significantly reduce or even avoid the use of capacitor components in the transmission path of the Doppler intermediate frequency signal, thus ensuring the immediacy of the Doppler intermediate frequency signal and facilitating the real-time detection of motions comprising human respiration and heartbeat.

Another object of the present invention is to provide an anti-interference microwave detection method and microwave detection device, wherein in the initial Doppler intermediate frequency signal state, which is a single-ended signal form, the differential signal form of the Doppler intermediate frequency signal is formed by converting the single-ended signal form, which is correspondingly advantageous to ensure the initial strength of the differential signal form of the Doppler intermediate frequency signal and to ensure the feedback accuracy of the Doppler intermediate frequency signal corresponding to the movement of objects in the corresponding detection space.

According to one aspect of the present invention, there is provided a microwave detection method that is resistant to interference. The interference-resistant microwave detection method comprises the following steps:
(A) emitting a detection beam corresponding to a local oscillator signal to form a corresponding detection space;
(B) receiving an echo formed by the detection beam which is reflected by a detected object in the detection space and generating a feedback signal;
(C) outputting a Doppler intermediate frequency signal in a differential signal form, wherein the Doppler intermediate frequency signal corresponds to the frequency/phase difference between the local oscillator signal and the feedback signal; and
(D) outputting the Doppler intermediate frequency signal which has been processed by frequency selective cancellation, wherein a common-mode interference, generated by a wireless communication signal in an environment interference signal superimposed on the feedback signal, is capable of being eliminated in the Doppler intermediate frequency signal, wherein the wireless communication signal has any frequency relationship selected from the group consisting of same frequency, adjacent frequency and harmonic frequency with a frequency of the local oscillator signal.

In an embodiment, in the step (D), a frequency selective cancellation circuit is used to perform the selective frequency cancellation on the Doppler intermediate frequency signal in the differential form output in the step (C), wherein the frequency selective cancellation circuit comprises a first equivalent resistance, a second equivalent resistance, and an equivalent capacitor, wherein one end of the first equivalent resistance is electrically connected to one end of the equivalent capacitor, and one end of the second equivalent resistance is electrically connected to the other end of the equivalent capacitor, wherein the other ends of the first and second equivalent resistances correspond to two input terminals of the frequency selective cancellation circuit, and two ends of the equivalent capacitor correspond to two output terminals of the frequency selective cancellation circuit, wherein the Doppler intermediate frequency signal in the differential form output in the step (C) is input from the two input terminals, and the Doppler intermediate frequency signal processed by the selective frequency cancellation is output from the two output terminals.

In an embodiment, wherein the first equivalent resistance and the second equivalent resistance are set to have a resistance value of approximately 39 kΩ within an error range of 25%, and the equivalent capacitor is set to have a capacitance of approximately 47 nF in an error range of 25%.

In an embodiment, wherein the equivalent capacitor is set in series with two capacitors, wherein the frequency selective cancellation circuit is grounded between the two series-connected capacitors.

In an embodiment, wherein each of the two input terminals of the frequency selective cancellation circuit is electrically connected to a ground capacitor.

In an embodiment, wherein between the step (C) and the step (D), and/or after the step (D), the anti-interference microwave detection method further comprises a step (E) of differentially amplifying the Doppler intermediate frequency signal in the differential form.

In an embodiment, wherein after the step (D), the anti-interference microwave detection method further comprises a step (F) of converting the Doppler intermediate frequency signal from the differential signal form to a single-ended signal form.

In an embodiment, wherein in the step (C), the Doppler intermediate frequency signal in the differential signal form corresponding to the frequency/phase difference between the local oscillator signal and the feedback signal is directly output in a frequency mixing process.

In an embodiment, wherein the step (C) comprises the following steps:
(C1) mixing the local oscillator signal and the feedback signal in the frequency conversion process, so that the Doppler intermediate frequency signal corresponding to the frequency/phase difference between the local oscillator signal and the feedback signal is extracted;
(C2) outputting the Doppler intermediate frequency signal in a single-ended signal form corresponding to the frequency/phase difference between the local oscillator signal and the feedback signal;
(C3) by inversely outputting the Doppler intermediate frequency signal in the single-ended signal form corresponding to the frequency/phase difference signal between the local oscillator signal and the feedback signal in an inverted manner, converting the Doppler intermediate frequency signal from the single-ended signal form to the differential signal form.

According to another aspect of the present invention, the present invention further provides a microwave detection device, comprising:
an oscillation unit which is configured for generating a local oscillator signal;
an antenna unit which is fed and connected to the oscillation unit to emit a corresponding detection beam corresponding to a frequency of the local oscillator signal to form a corresponding detection space, and to receive an echo formed by the detection beam which is reflected by a detected object in the detection space, so as to generate a feedback signal;
a Doppler differential output circuit which is electrically connected to the antenna unit and the oscillation unit to output a Doppler intermediate frequency signal in a differential signal form, wherein the Doppler intermediate frequency signal corresponds to the frequency/phase difference between the local oscillator signal and the feedback signal; and
at least a frequency selective cancellation circuit which is electrically connected to the Doppler differential output circuit for eliminating a predetermined frequency range in the Doppler intermediate frequency signal in the differential signal form through frequency selective cancellation, so as to eliminate the common-mode interference in the Doppler intermediate frequency signal, which is caused by a wireless communication signal with any predetermined frequency relationship with a frequency of the local oscillator signal, in the environment interference signal superimposed on the feedback signal in the differential signal form, wherein the predetermined frequency relationship is selected from the group consisting of same frequency, adjacent frequency, and harmonic frequency.

In an embodiment, wherein the frequency selective cancellation circuit comprises a first equivalent resistance, a second equivalent resistance, and an equivalent capacitor, wherein one end of the first equivalent resistance is electrically connected to one end of the equivalent capacitor, and one end of the second equivalent resistance is electrically connected to the other end of the equivalent capacitor, wherein the frequency selective cancellation circuit, which adopts the other end of the first equivalent resistance and the other end of the second equivalent resistance as two input terminals, and two ends of the equivalent capacitor as two output terminals, inputs the Doppler intermediate frequency signal in the differential signal form output by the Doppler differential output circuit from the two input terminals, and outputs the Doppler intermediate frequency signal that has been processed by the frequency selective cancellation from the two output terminals.

In an embodiment, wherein the first equivalent resistance and the second equivalent resistance are set to have a resistance value of approximately 39 kΩ within an error range of 25%, and the equivalent capacitor is set to have a capacitance of approximately 47 nF in an error range of 25%.

In an embodiment, wherein the equivalent capacitor is set in series with two capacitors, wherein the frequency selective cancellation circuit is grounded between the two series-connected capacitors.

In an embodiment, wherein each of the two input terminals of the frequency selective cancellation circuit is electrically connected to a ground capacitor.

In an embodiment, wherein the Doppler differential output circuit is configured to directly output the Doppler intermediate frequency signal in the differential signal form corresponding to the frequency/phase difference between the local oscillator signal and the feedback signal in a frequency mixing process.

In an embodiment, wherein the Doppler differential output circuit comprises a first load and a second load each formed in a form of equivalent resistance or equivalent inductance, a first MOS transistor, and a second MOS transistor, wherein one end of the first load is electrically connected to one end of the second load, and the other end of the first load is electrically connected to a drain of the first MOS transistor, wherein the other end of the second load is electrically connected to a drain of the second MOS transistor, wherein a source of the first MOS transistor is electrically connected to a source of the second MOS transistor, wherein two ends of the interconnected first load and second loads are connected to a power supply, and two sources of the interconnected first MOS transistor and second MOS transistor are arranged to receive the feedback signal, wherein gate electrodes of the first MOS transistor and the second MOS transistor are respectively arranged to receive an inverted local oscillator signal, wherein the Doppler intermediate frequency signal in the differential signal form is output from the drains of the first MOS transistor and the second MOS transistor.

In an embodiment, wherein the Doppler differential output circuit comprises a first MOS transistor, a second MOS transistor, a third MOS transistor, and a fourth MOS transistor, wherein a drain of the first MOS transistor is electrically connected to a drain of the second MOS transistor, and a drain of the third MOS transistor is electrically connected to a drain of the fourth MOS transistor, wherein a source of the first MOS transistor is electrically connected to a source of the third MOS transistor, and a source of the second MOS transistor is electrically connected to a source of the fourth MOS transistor, wherein the feedback signal in opposite phase is input between the two drains of the first MOS transistor and the second MOS transistor, and between the two drains of the third MOS transistor and the fourth MOS transistor respectively, wherein four gates of the first MOS transistor, the second MOS transistor, the third MOS transistor, and the fourth MOS transistor are input with the local oscillator signal in reverse phase, wherein the Doppler intermediate frequency signals in the differential signal form is capable of being output between the two sources of the first MOS transistor and the third MOS transistor, and between the two sources of the second MOS transistor and the fourth MOS transistor.

In an embodiment, wherein the Doppler differential output circuit comprises a first load and a second load each formed in the form of equivalent resistor or equivalent inductance, a first MOS transistor, a second MOS transistor, and a third MOS transistor, wherein one end of the first load is electrically connected to one end of the second load, and the other end of the first load is electrically connected to a drain of the first MOS transistor, wherein the other end of the second load is electrically connected to a drain of the second MOS transistor, wherein a source of the first MOS transistor and a source of the second MOS transistor are electrically connected to a drain of the third MOS transistor, wherein a source of the third MOS transistor is grounded, wherein two ends of the interconnected first load and second load are connected to a power supply, wherein a gate of the third MOS transistor is configured to receive the feedback signal, wherein gates of the first MOS transistor and the second MOS transistor are respectively input with inverted local oscillator signal, so that the Doppler intermediate frequency signal in the differential signal form is output from the drain of the first MOS transistor and the drain of the second MOS transistor.

In an embodiment, wherein the Doppler differential output circuit comprises a first load and a second load each formed in the form of equivalent resistance or equivalent inductance, a first MOS transistor, a second MOS transistor, a third MOS transistor, a fourth MOS transistor, a fifth MOS transistor, a sixth MOS transistor, and a current source, wherein one end of the first load is electrically connected to one end of the second load, and the other end of the first load is respectively electrically connected to a drain of the first MOS transistor and a drain of the third MOS transistor, wherein the other end of the second load is respectively electrically connected to a drain of the second MOS transistor and a drain of the fourth MOS transistor, wherein a source of the first MOS transistor and a source of the second MOS transistor are electrically connected to a drain of the fifth MOS transistor, wherein a source of the third MOS transistor and a source of the fourth MOS transistor are electrically connected to a drain of the sixth MOS transistor, wherein a source of the fifth MOS transistor and a source of the sixth MOS transistor are electrically connected to the current source, wherein the feedback signal in opposite phase is respectively input to gates of the fifth MOS transistor and the sixth MOS transistor, wherein the local oscillator signal in opposite phase is respectively input to gates of the first MOS transistor and the second MOS transistor, wherein the local oscillator signal in opposite phase is respectively input to gates of the third MOS transistor and the fourth MOS transistor, wherein the local oscillator signal in the same phase is input to gates of the second MOS transistor and the third MOS transistor, wherein two ends of the interconnected first load and second load are connected to a power supply, wherein the Doppler intermediate frequency signal in the differential signal form is output from the other end of the first load and the other end of the second load.

In an embodiment, wherein the Doppler differential output circuit comprises a mixer circuit and a single-ended signal to differential signal conversion circuit, wherein the mixer circuit is electrically connected to the antenna unit and the oscillation unit to access the feedback signal and the local oscillator signal, and outputs a corresponding single-ended signal form of the Doppler intermediate frequency signal in a mixing detection manner, which corresponds to the frequency/phase difference between the feedback signal and the local oscillator signal, wherein the single-ended signal to differential signal conversion circuit is electrically connected to the mixer circuit to access the single-ended signal form of the Doppler intermediate frequency signal, wherein by reversing the single-ended form of the Doppler intermediate frequency signal, the single-ended signal form of the Doppler intermediate frequency signal is converted into the differential signal form of the Doppler intermediate frequency signal.

In an embodiment, wherein the microwave detection device further comprises at least a differential amplifier circuit which is set between the Doppler differential output circuit and the frequency selective cancellation circuit to differentially amplify the Doppler intermediate frequency signal in the differential signal form output by the Doppler differential output circuit.

In an embodiment, wherein the microwave detection device further comprises at least a differential amplifier circuit, wherein the differential amplifier circuit is set at two output terminals of the frequency selective cancellation circuit to differentially amplify the Doppler intermediate frequency signal in the differential signal form which is output from the frequency selective cancellation circuit.

In an embodiment, wherein the microwave detection device further comprises a differential signal to single-ended signal conversion circuit which is used to access the Doppler intermediate frequency signal in the differential signal form after the frequency selective cancellation, and convert the differential signal form of the Doppler intermediate frequency signal into a single-ended signal form of the Doppler intermediate frequency signal for output.

According to another aspect of the present invention, the present invention further provides a microwave detection device, comprising:
an oscillation unit which is configured for generating a local oscillator signal;
an antenna unit which is fed and connected to the oscillation unit to emit a corresponding detection beam corresponding to a frequency of the local oscillator signal to form a corresponding detection space, and to receive an echo formed by the detection beam which is reflected by a detected object in the detection space, so as to generate a feedback signal; and
a Doppler differential output circuit which is electrically connected to the antenna unit and the oscillation unit to output a Doppler intermediate frequency signal in a differential signal form, wherein the Doppler intermediate frequency signal corresponds to the frequency/phase difference between the local oscillator signal and the feedback signal.

In an embodiment, wherein the Doppler differential output circuit comprises a first load and a second load each formed in a form of equivalent resistance or equivalent inductance, a first MOS transistor, and a second MOS transistor, wherein one end of the first load is electrically connected to one end of the second load, and the other end of the first load is electrically connected to a drain of the first MOS transistor, wherein the other end of the second load is electrically connected to a drain of the second MOS transistor, wherein a source of the first MOS transistor is electrically connected to a source of the second MOS transistor, wherein two ends of the interconnected first load and second loads are connected to a power supply, and two sources of the interconnected first MOS transistor and second MOS transistor are arranged to receive the feedback signal, wherein gate electrodes of the first MOS transistor and the second MOS transistor are respectively arranged to receive an inverted local oscillator signal, wherein the Doppler intermediate frequency signal in the differential signal form is output from the drains of the first MOS transistor and the second MOS transistor.

In an embodiment, wherein the Doppler differential output circuit comprises a first MOS transistor, a second MOS transistor, a third MOS transistor, and a fourth MOS transistor, wherein a drain of the first MOS transistor is electrically connected to a drain of the second MOS transistor, and a drain of the third MOS transistor is electrically connected to a drain of the fourth MOS transistor, wherein a source of the first MOS transistor is electrically connected to a source of the third MOS transistor, and a source of the second MOS transistor is electrically connected to a source of the fourth MOS transistor, wherein the feedback signal in opposite phase is input between the two drains of the first MOS transistor and the second MOS transistor, and between the two drains of the third MOS transistor and the fourth MOS transistor respectively, wherein four gates of the first MOS transistor, the second MOS transistor, the third MOS transistor, and the fourth MOS transistor are input with the local oscillator signal in reverse phase, wherein the Doppler intermediate frequency signals in the differential signal form is capable of being output between the two sources of the first MOS transistor and the third MOS transistor, and between the two sources of the second MOS transistor and the fourth MOS transistor.

In an embodiment, wherein the Doppler differential output circuit comprises a first load and a second load each formed in the form of equivalent resistor or equivalent inductance, a first MOS transistor, a second MOS transistor, and a third MOS transistor, wherein one end of the first load is electrically connected to one end of the second load, and the other end of the first load is electrically connected to a drain of the first MOS transistor, wherein the other end of the second load is electrically connected to a drain of the second MOS transistor, wherein a source of the first MOS transistor and a source of the second MOS transistor are electrically connected to a drain of the third MOS transistor, wherein a source of the third MOS transistor is grounded, wherein two ends of the interconnected first load and second load are connected to a power supply, wherein a gate of the third MOS transistor is configured to receive the feedback signal, wherein gates of the first MOS transistor and the second MOS transistor are respectively input with inverted local oscillator signal, so that the Doppler intermediate frequency signal in the differential signal form is output from the drain of the first MOS transistor and the drain of the second MOS transistor.

In an embodiment, wherein the Doppler differential output circuit comprises a first load and a second load each formed in the form of equivalent resistance or equivalent inductance, a first MOS transistor, a second MOS transistor, a third MOS transistor, a fourth MOS transistor, a fifth MOS transistor, a sixth MOS transistor, and a current source, wherein one end of the first load is electrically connected to one end of the second load, and the other end of the first load is respectively electrically connected to a drain of the first MOS transistor and a drain of the third MOS transistor, wherein the other end of the second load is respectively electrically connected to a drain of the second MOS transistor and a drain of the fourth MOS transistor, wherein a source of the first MOS transistor and a source of the second MOS transistor are electrically connected to a drain of the fifth MOS transistor, wherein a source of the third MOS transistor and a source of the fourth MOS transistor are electrically connected to a drain of the sixth MOS transistor, wherein a source of the fifth MOS transistor and a source of the sixth MOS transistor are electrically connected to the current source, wherein the feedback signal in opposite phase is respectively input to gates of the fifth MOS transistor and the sixth MOS transistor, wherein the local oscillator signal in opposite phase is respectively input to gates of the first MOS transistor and the second MOS transistor, wherein the local oscillator signal in opposite phase is respectively input to gates of the third MOS transistor and the fourth MOS transistor, wherein the local oscillator signal in the same phase is input to gates of the second MOS transistor and the third MOS transistor, wherein two ends of the interconnected first load and second load are connected to a power supply, wherein the Doppler intermediate frequency signal in the differential signal form is output from the other end of the first load and the other end of the second load

Still further objects and advantages will become apparent from a consideration of the ensuing description and drawings.

These and other objectives, features, and advantages of the present invention will become apparent from the following detailed description, the accompanying drawings, and the appended claims.

### BRIEF DESCRIPTION OF THE DRAWINGS

FIG. 1 is a schematic diagram illustrating a circuit structure principle of a conventional Doppler microwave detection device.

FIG. 2 is a comparison diagram illustrating the Doppler intermediate frequency signal output by the conventional Doppler microwave detection device before and after being filtered.

FIG. 3 is a schematic diagram illustrating a structural principle of a microwave detection device according to an embodiment of the present invention.

FIG. 4A is a comparative diagram illustrating the Doppler intermediate frequency signals output from the microwave detection device of the above mentioned embodiment of the present invention before and after the frequency selective cancellation processing.

FIG. 4B is a comparative schematic diagram illustrating the Doppler intermediate frequency signal output by the microwave detection device of the above mentioned embodiment of the present invention before and after the frequency selective cancellation processing.

FIG. 5A is a schematic diagram illustrating the structural principle of the microwave detection device according to an alternative mode of the above mentioned embodiment of the present invention.

FIG. 5B is a schematic diagram illustrating the structural principle of the microwave detection device according to a further modification of the above mentioned embodiment according of the present invention.

FIG. 6A is a schematic diagram of the structural principle of the microwave detection device of another variant embodiment of the above embodiment according to the present invention.

FIG. 6B is a schematic diagram comparing the Doppler intermediate frequency signals output at different positions by the microwave detection device of the above-mentioned modified embodiment according to the present invention.

FIG. 7A is a schematic diagram illustrating a series connection structure of the frequency selective cancellation circuit of the microwave detection device according to the above mentioned embodiment of the present invention.

FIG. 7B is a schematic diagram illustrating a parallel connection structure of the frequency selective cancellation circuit of the microwave detection device according to the above mentioned embodiment of the present invention.

FIGS. 8A to 8D are respectively schematic diagrams illustrating different circuit structures of the Doppler differential output circuit of the microwave detection device according to the above mentioned embodiment of the present invention.

FIG. 9 is a schematic diagram illustrating a circuit structure principle of the Doppler differential output circuit of the microwave detection device according to the above mentioned embodiment of the present invention.

FIG. 10A is a schematic diagram illustrating a circuit structure based on the above circuit structure principle of the Doppler differential output circuit of the microwave detection device according to the above mentioned embodiment of the present invention.

FIG. 10A is a schematic diagram illustrating another circuit structure based on the above circuit structure principle of the Doppler differential output circuit of the microwave detection device according to the above mentioned embodiment of the present invention.

FIGS. 11A to 11D are respectively schematic diagrams illustrating different circuit structures based on the above circuit structure principle of the Doppler differential output circuit of the microwave detection device according to the above mentioned embodiment of the present invention.

FIGS. 12A to 12C are respectively schematic diagrams illustrating different circuit structures based on the above circuit structure principle of the Doppler differential output circuit of the microwave detection device according to the above mentioned embodiment of the present invention.

FIG. 13A is a schematic diagram illustrating another circuit structure based on the above circuit structure principle of the Doppler differential output circuit of the microwave detection device according to the above mentioned embodiment of the present invention.

FIG. 13B is a schematic diagram illustrating another circuit structure based on the above circuit structure principle of the Doppler differential output circuit of the microwave detection device according to the above mentioned embodiment of the present invention.

FIG. 14A is a partial schematic diagram illustrating a microwave detection device according another embodiment of the present invention.

FIG. 14B is a partial schematic diagram of the microwave detection device according to another embodiment of the present invention.

FIG. 15A is a schematic diagram illustrating the circuit structure principle of the microwave detection device being provided with a differential amplifier circuit according to the above mentioned embodiment of the present invention.

FIG. 15B is a schematic diagram illustrating another circuit structure principle of the microwave detection device being provided with a differential amplifier circuit according to the above mentioned embodiment of the present invention.

FIG. 16 is a schematic diagram illustrating the circuit structure of the differential amplifier circuit of the microwave detection device according to the above mentioned embodiment of the present invention.

FIG. 17A is a schematic diagram illustrating a schematic diagram of the circuit structure principle of the microwave detection device which is provided with a differential signal to single-ended signal conversion circuit according to the above mentioned embodiment of the present invention.

FIG. 17B is a schematic diagram illustrating another circuit structure principle of the microwave detection device which is provided with a differential signal to single-ended signal conversion circuit according to the above mentioned embodiment of the present invention.

FIG. 18 is a schematic diagram illustrating the circuit structure of the differential signal to single-ended signal conversion circuit of the microwave detection device according to the above embodiment of the present invention.

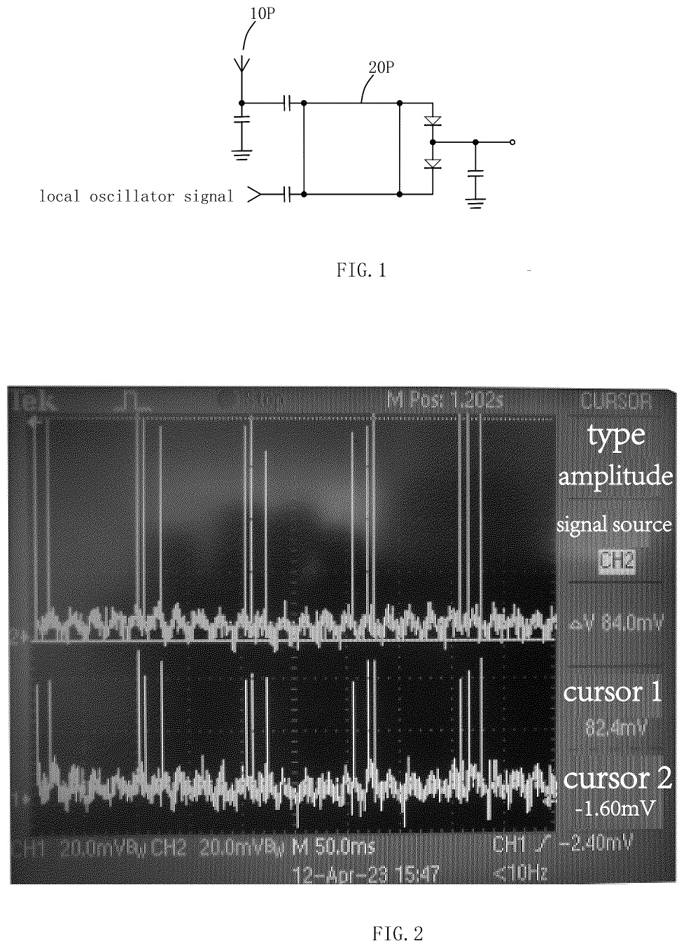

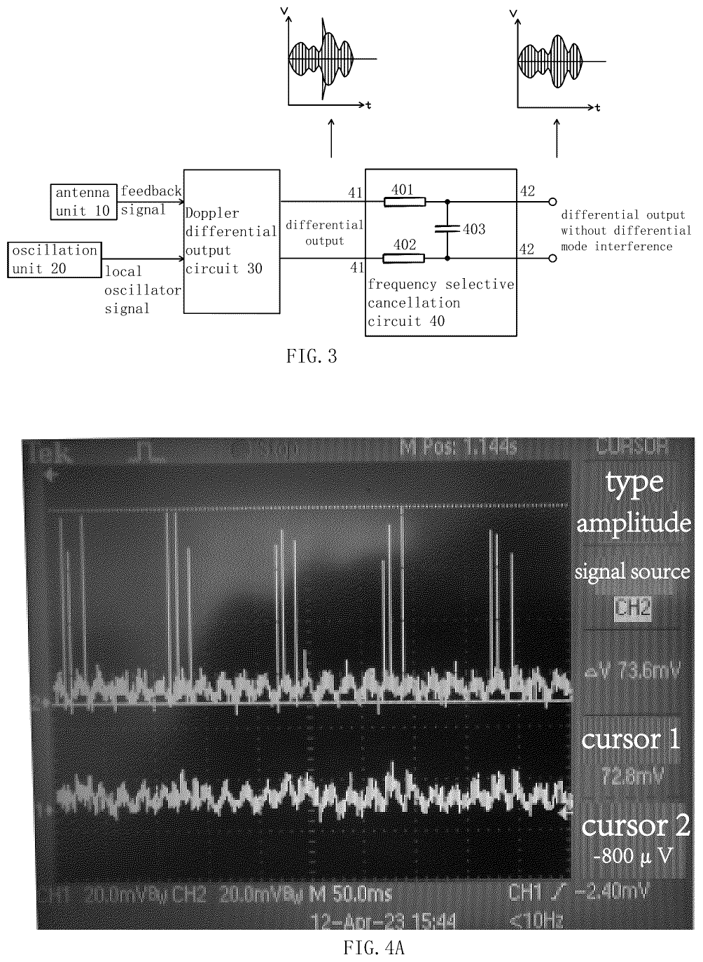

### DETAILED DESCRIPTION OF THE PREFERRED EMBODIMENT

The following description is disclosed to enable any person skilled in the art to make and use the present invention. Preferred embodiments are provided in the following description only as examples and modifications will be apparent to those skilled in the art. The general principles defined in the following description would be applied to other embodiments, alternatives, modifications, equivalents, and applications without departing from the spirit and scope of the present invention.

Those skilled in the art should understand that, in the disclosure of the present invention, terminologies of “longitudinal,” “lateral,” “upper,” “front,” “back,” “left,” “right,” “perpendicular,” “horizontal,” “top,” “bottom,” “inner,” “outer,” and etc. that indicate relations of directions or positions are based on the relations of directions or positions shown in the appended drawings, which are only to facilitate descriptions of the present invention and to simplify the descriptions, rather than to indicate or imply that the referred device or element is limited to the specific direction or to be operated or conFig.d in the specific direction. Therefore, the above-mentioned terminologies shall not be interpreted as confine to the present invention.

It can be understood that the term “one”, “a”, or “an” should be understood as “at least one” or “one or more”, that is, in one embodiment, the number of components can be one, while in another embodiment, the number of the component can be multiple. The term “one” “a”, or “an” cannot be understood as a limitation on the quantity.

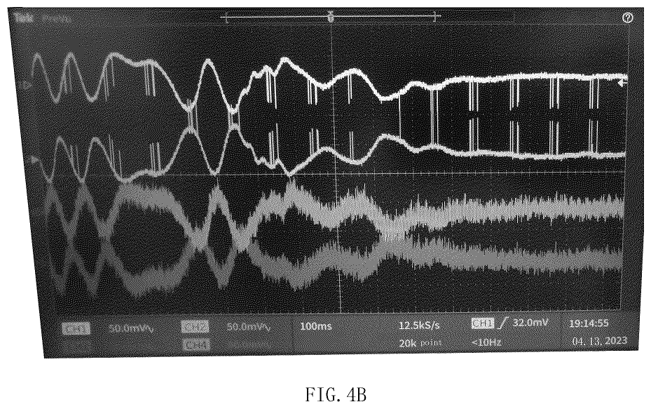

The present invention provides an anti-interference microwave detection method and microwave detection device. Referring to FIG. 3 of the drawings, the structural principle of the microwave detection device according to an embodiment of the present invention is illustrated. The microwave detection device comprises an antenna unit 10, an oscillation unit 20, a Doppler differential output circuit 30, and at least one frequency selective cancellation circuit 40. The oscillation unit 20 is configured to generate a local oscillation signal, and the antenna unit 10 is fed to the oscillation unit 20 to transmit a detection beam corresponding to the frequency of the local oscillation signal to form a corresponding detection space, and to receive a reflected signal generated by the reflection of the detection beam by an object in the detection space, thereby forming a feedback signal. The Doppler differential output circuit 30 is electrically connected to the antenna unit 10 and the oscillation unit 20 to output a Doppler intermediate frequency signal in a differential signal form, wherein the Doppler intermediate frequency signal corresponds to the frequency/phase difference between the local oscillation signal and the feedback signal. The frequency selective cancellation circuit 40 is electrically connected to the Doppler differential output circuit 30 to eliminate the differential signal in the predetermined selected frequency range of the Doppler intermediate frequency signal in a frequency selective cancellation manner.

It is worth mentioning that in some embodiments of the present invention, the antenna unit 10 is set to a same antenna body as the transmitting antenna and the receiving antenna, and is electrically connected to the oscillation unit 20 and the Doppler differential output circuit 30. In other embodiments of the present invention, the antenna unit 10 may comprises different antenna bodies which respectively function as the transmitting antenna connected to the oscillation unit 20 and the receiving antenna connected to the Doppler differential output circuit 30. The present invention does not limit the number and shape of the corresponding antenna bodies.

It is also worth mentioning that in the state where the oscillation unit 20 is electrically connected to the antenna unit 10 and electrically connected to the Doppler differential output circuit 30, the connection line between the antenna unit 10 and the oscillation unit 20 and the connection line between the Doppler differential output circuit 30 and the oscillation unit 20 are not limited to be the same. That is, the local oscillator signal provided by the oscillation unit 20 to the antenna unit 10 and the local oscillator signal provided to the Doppler differential output circuit 30 are homogenous (both provided by the oscillation unit 20), but not limited to be in the same path. In some embodiments of the present invention, the oscillation unit 20 is based on the corresponding circuit to amplify and output the local oscillator signal to the antenna unit 10, the present invention does not limit this.

It can be understood that based on the above working principle of the Doppler microwave detection device, on one hand, environmental interference signals that can be received by the antenna unit 10 will be superimposed on the the differential signal form of the Doppler intermediate frequency signal and form the first type of interference signal in the Doppler intermediate frequency signal. On the other hand, signals in the environmental interference that can be received by the antenna unit 10 and have a frequency relationship with the local oscillator signal, such as the same frequency, adjacent frequency, or harmonic frequency, will also be superimposed on the feedback signal and participate in the mixing and detection process to form the second type of interference signal that is mixed with the effective signal in the Doppler intermediate frequency signal.

Based on the above formation process of the first type of interference signal and the second type of interference signal, the first type of interference signal and the second type of interference signal correspond respectively to the common-mode interference and differential-mode interference existing in the differential signal form of the Doppler intermediate frequency signal, which can be distinguished and then based on different signal processing methods to respectively suppress or eliminate the first type of interference signal and the second type of interference signal in the Doppler intermediate frequency signal in the differential signal form without affecting each other. This is conducive to ensure the integrity of the Doppler intermediate frequency signal and the accuracy of the feedback of the detection of the motion of objects in the corresponding detection space, and is conducive to realize combined detection of motion characteristics comprising human movement, micro-motion, breathing, and heartbeat, and thus the detection function of the microwave detection device is rich and suitable for intelligent detection applications with multi-functional requirements.

Specifically, in this embodiment of the present invention, the frequency selective cancellation circuit 40 is used to eliminate the second type of interference signal in the corresponding frequency range of the Doppler intermediate frequency signal by frequency selective cancellation. The frequency selective cancellation circuit 40 comprises a first equivalent resistance 401, a second equivalent resistance 402, and an equivalent capacitor 403. One end of the first equivalent resistance 401 is electrically connected to one end of the equivalent capacitor 403, and one end of the second equivalent resistance 402 is electrically connected to the other end of the equivalent capacitor 403. The frequency selective cancellation circuit 40 comprises two input terminals 41, which correspond to the other end of the first equivalent resistance 401 and the other end of the second equivalent resistance 402. The frequency selective cancellation circuit 40 comprises two output terminals 42, which correspond to the two ends of the equivalent capacitor 403. The frequency selective cancellation circuit 40 is electrically connected to the Doppler differential output circuit 30 at the two input terminals 41, and the two poles of the Doppler intermediate frequency signal in differential signal form are connected to the two input terminals 41. The frequency selective cancellation circuit 40 outputs the Doppler intermediate frequency signal that has been processed by frequency selective cancellation at the two output terminals 42.

It can be understood that the equivalent resistance is formed by a single or multiple resistive elements connected in series, parallel, or series-parallel combination to meet the corresponding resistance requirements, without limiting the form, quantity, and connection mode of the corresponding resistive elements. Similarly, the equivalent capacitor 403 is formed by a single or multiple capacitive elements connected in series, parallel, or series-parallel combination to meet the corresponding capacitance requirements, without limiting the form, quantity, and connection mode of the corresponding capacitive elements.

It is worth mentioning that in practical applications, the environmental interference signals with the same frequency, adjacent frequency or harmonic frequency relationship with the local oscillator signal of the microwave detection device is mainly wireless communication signals. Through the exploration of the principle of wireless communication and the actual testing of different products, it is found that in the wireless communication signal based on the frequency modulation working principle and expressing communication information through frequency changes, the frequency change rate of the signal is much higher than that of the feedback signal based on the Doppler effect principle corresponding to the normal moving object, and the corresponding second type of interference signal exists in the form of high-frequency peak in the differential signal form of the Doppler intermediate frequency signal. Therefore, the second type of interference signal in the corresponding frequency range of the differential signal form of the Doppler intermediate frequency signal can be accurately eliminated based on the selective cancellation method, so as to ensure the ability of the microwave detection device to resist communication interference and have significant practical value and commercial significance.

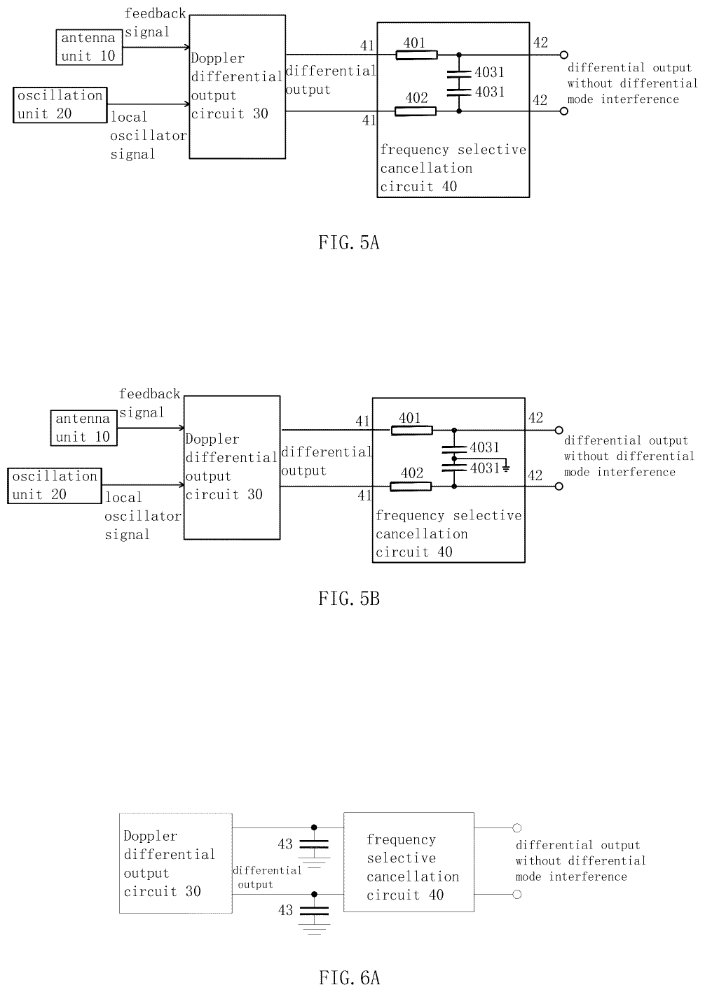

Specifically, referring to FIG. 4A of the drawings of the present invention, corresponding to the microwave detection device shown in FIG. 3, when there is no object activity in the detection space, one of the input terminal 41 of the frequency selective cancellation circuit 40 and one of the output terminals 42 of the frequency selective cancellation circuit 40 are sampled to obtain the Doppler intermediate frequency signals (the differential signal is in a single-pole-to-ground state) and are arranged upside and down so as to be compared, and the selective frequency cancellation method can accurately eliminate the second type of interference signal in the corresponding frequency range of the differential signal form of the Doppler intermediate frequency signal, which is clearly different from the integration smoothing process of the filtering method, thus avoiding the use of multiple filtering methods and benefiting the integrity of the Doppler intermediate frequency signal and the corresponding relationship between its parameters and physical representing meaning, thereby improving the feedback accuracy of the Doppler intermediate frequency signal for the detection of the motion of objects in the corresponding detection space.

Furthermore, referring to FIG. 4B of the description and drawings of the present invention, in the microwave detection device corresponding to the example shown in FIG. 3, when there is human activity in the detection space, the two input terminals 41 and the two output terminals 42 the frequency selective cancellation circuit 40 are respectively sampled to obtain the corresponding Doppler intermediate frequency signals (complete form of differential signal) and are arranged upside and down so as to be compared. It is also apparent that the frequency selective cancellation method can accurately eliminate the second type of interference signal in the corresponding frequency range of the Doppler intermediate frequency signal, thus avoiding the need for multiple filtering and ensuring the integrity of the Doppler intermediate frequency signal and the corresponding relationship between its parameters and physical representing meaning, thereby improving the feedback accuracy of the Doppler intermediate frequency signal for the detection of movement of objects in the corresponding detection space.

In addition, since the frequency selective cancellation method can accurately eliminate the second type of interference signal in the corresponding frequency range of the Doppler intermediate frequency signal, avoiding the signal delay caused by filtering processing and ensuring the real-time nature of the Doppler intermediate frequency signal, it is advantageous for the real-time detection of human actions comprising human breathing and heartbeat.

Specifically, in order to maintain the differential signal form of the Doppler intermediate frequency signal output from the two output terminals 42 of the frequency selective cancellation circuit 40, in this embodiment of the present invention, the resistance values of the first equivalent resistance 401 and the second equivalent resistance 402 are set to be within 25% error range and tend to be the same. For example, when the microwave detection device is set to operate in the 5.8 GHz ISM band, the first equivalent resistance 401 and the second equivalent resistance 402 are preferably set to be within 25% error range and tend to have a resistance value of 39 kΩ respectively. Correspondingly, the equivalent capacitor 403 being set to be within 25% error range and tending to have a capacitance of 47 nF, such as a capacitor with a model number of 473. This is done so that the selected frequency range of the frequency selective cancellation circuit 40 can correspond to the frequency of the second type of interference signal generated in the differential signal form of the Doppler intermediate frequency signal generated by existing wireless communication signals, so as to accurately eliminate the second type of interference signal in the corresponding frequency range of the differential signal form of the Doppler intermediate frequency signal, and output the Doppler intermediate frequency signal that has been processed by frequency selective cancellation in a lossless state, thereby ensuring the integrity of the Doppler intermediate frequency signal and the corresponding relationship between its parameters and physical representing meaning. Therefore, compared with the method of multiple filtering, it can significantly improve the feedback accuracy of the Doppler intermediate frequency signal corresponding to the motion of objects in the corresponding detection space.

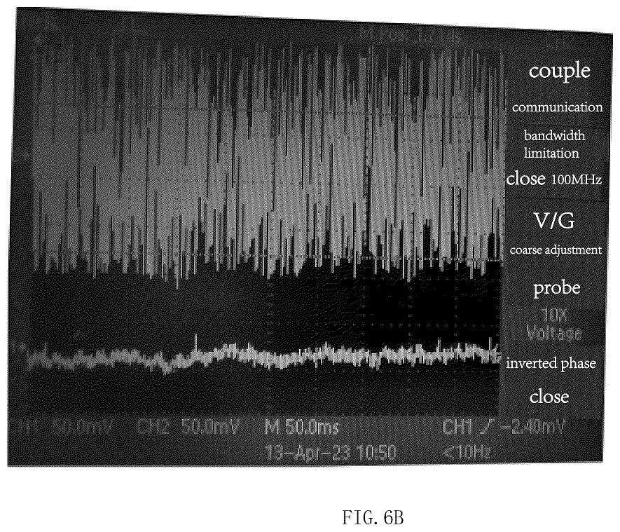

Furthermore, referring to FIG. 5A of the drawings of the present invention, based on the structure of the microwave detection device shown in the example of FIG. 3, a schematic diagram illustrating the structure of the microwave detection device of a deformation embodiment of the present invention is shown, this embodiment is an alternative mode based on the deformation of the number and connection mode of corresponding capacitive elements that form the equivalent capacitor 403. In this modified embodiment of the present invention, the equivalent capacitor 403 is equivalently set by two capacitors 4031 connected in series, preferably using the same type of capacitor, to maintain the differential signal form of the Doppler intermediate frequency signal output from the two output terminals 42 of the frequency selective cancellation circuit 40. For example, when the microwave detection device is set to operate in the ISM band of 5.8 GHz, the first equivalent resistance 401 and the second equivalent resistance 402 are preferably set to have a resistance value of 39 kΩ within a 25% error range, and the equivalent capacitor 403 is set to have a capacitance of 47 nF within a 25% error range. Correspondingly, two capacitors 4031 of the same type are both set to a capacitance of 100 nF within a 25% error range, such as using capacitors with a model number of 104.

Furthermore, referring to FIG. 5B of the drawings of the present invention, on the basis of the structure of the microwave detection device shown in FIG. 5A, the frequency selective cancellation circuit 40 can optionally be grounded between the two serially connected capacitors 4031 to form a balanced ground consumption of the corresponding frequency range of signals in the differential Doppler intermediate frequency signal, thereby ensuring that the frequency selective cancellation circuit 40 outputs the differential Doppler intermediate frequency signal in a differential signal form at the two output terminals 42.

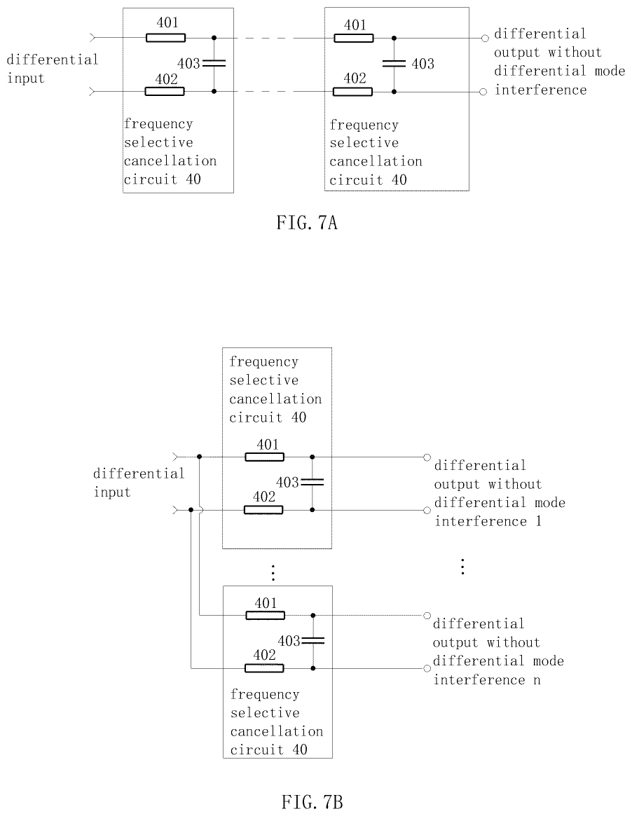

In addition, referring to FIG. 6A of the drawings of the present invention, a further modified structure of the microwave detection device according to the above mentioned embodiment of the present invention is illustrated. Due to the fact that in the application scenario of the microwave detection device, the environment interference signal with the same frequency relationship as the local oscillator signal of the microwave detection device may also be the signal emitted by other microwave detection devices with the same frequency, or the same frequency interference signal formed based on multiple reflections in small space and/or strong reflection environment of the detection beam emitted by the microwave detection device. Correspondingly, the first and second types of interference signals exist in the form of spikes in the differential signal form of the Doppler intermediate frequency signal. Before selectively canceling the second type of interference signal in the differential signal form of the Doppler intermediate frequency signal in a frequency range corresponding to the selected frequency shown in FIG. 6A, at least one of the frequency selective cancellation circuit 40 of the microwave detection device may optionally comprises the two input terminals 41 each of which is electrically connected to a ground capacitor 43. Based on the setting of the two ground capacitors 43, the first type of interference signal and the second type of interference signal, which are formed in the form of spikes in the differential signal of the multi-Doppler intermediate frequency signal due to the same frequency interference of the fixed frequency form, are suppressed, thus ensuring the anti-interference ability of the microwave detection device in the application scenarios of multiple microwave detection devices, as well as the anti-self-excitation interference ability in small spaces and/or strong reflection environments. In order to maintain the differential signal form of the Doppler intermediate frequency signals output from the two output terminals 42 of the frequency selective cancellation circuit 40, the two ground capacitors 43 are set to use capacitors of the same model, so that the capacitance of the two ground capacitors 43 tends to be the same.

Based on the corresponding beneficial effects demonstrated, referring to FIG. 6B of the drawings of the present invention, in a state where there is no object activity in the detection space, another microwave detection device operating at the same frequency may function as an interference source for the microwave detection device. In the microwave detection device shown in FIG. 6A, a front end of one of the input terminals 41 of the frequency selective cancellation circuit 40 which is connected to the ground capacitor 43 and one of the output terminals 42 of the frequency selective cancellation circuit 40 are sampled to obtain the upside-down arranged Doppler intermediate frequency signals (differential signal in single-pole-to-ground state). It is clearly visible that the fixed-frequency interference of the same frequency can be suppressed based on the setting of the ground capacitor 43 for the first type of interference signal and the second type of interference signal formed in the form of spikes in the differential signal form of the Doppler intermediate frequency signal, so as to avoid the high noise of the Doppler intermediate frequency signal output by the frequency selective cancellation circuit 40, thereby further ensuring the anti-interference ability of the microwave detection device in different application scenarios.

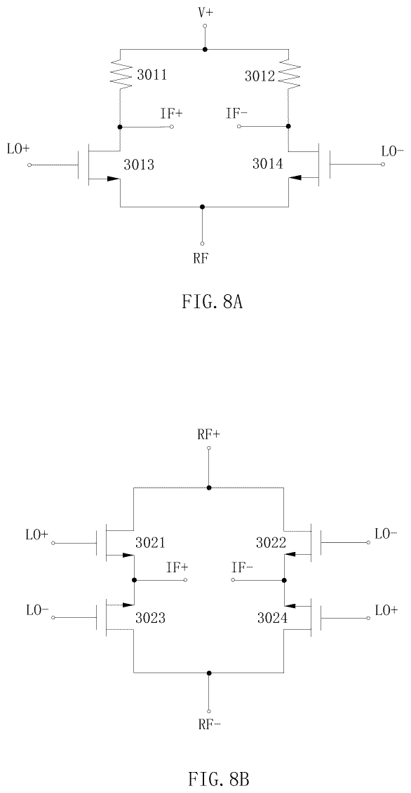

Furthermore, referring to FIGS. 7A and 7B of the drawings of the present invention, the number of the frequency selective cancellation circuits 40 is set to be multiple in a form based on the demand for multi-stage and/or multi-path frequency selective cancellation processing, and the electrical connection relationship between multiple frequency selective cancellation circuits 40 is not limited to series or parallel connection, but can also be formed based on a combination of series and parallel connections.

Corresponding to FIG. 7A, a series structure between the two frequency selective cancellation circuits 40 is illustrated. More specifically, the two output terminals 42 of one frequency selective cancellation circuit 40 are electrically connected to the two input terminals 41 of another frequency selective cancellation circuit 40, thereby forming a series structure between the two frequency selective cancellation circuits 40. The differential Doppler intermediate frequency signal is input to the two input terminals 41 of the frequency selective cancellation circuit 40 in the front stage, and the Doppler intermediate frequency signal processed by multi-stage selective frequency cancellation is output from the two output terminals 42 of the frequency selective cancellation circuit 40 in the back stage.

Corresponding to FIG. 7B, a parallel structure between two frequency selective cancellation circuits 40 is indicated. Specifically, one of the Input Terminals 41 of one of the frequency selective cancellation circuits 40 is electrically connected to one of the input terminals 41 of the other frequency selective cancellation circuit 40, thereby forming a parallel structure between the two frequency selective cancellation circuits 40. This enables multi-channel frequency selective cancellation processing of the Doppler intermediate frequency signal processed by each of the frequency selective cancellation circuits 40 at their respective output terminals 42 after being selected for frequency cancellation.

Corresponding to the structure of the microwave detection device in the above embodiments, the anti-interference microwave detection method of the present invention comprises the following steps.

(A) emit the detection beam corresponding to the lock oscillator signal to form the corresponding detection space.

(B) receive the echo formed by the detection beam which is reflected by the detected object in the detection space and generate the feedback signal.

(C) output the Doppler intermediate frequency signal in a differential signal form, wherein the Doppler intermediate frequency signal corresponds to the frequency/phase difference between the local oscillator signal and the feedback signal.

(D) output the Doppler intermediate frequency signal which has been processed by frequency selective cancellation.

The oscillation unit 20 provides the local oscillator signal, the antenna unit 10 transmits the detection beam and receives the echo, the Doppler differential output circuit 30 outputs the Doppler intermediate frequency signal in the form of differential signal by phase-inverting the frequency/phase difference between the local oscillator signal and the feedback signal when accessing the local oscillator signal and the feedback signal, and the frequency selective cancellation circuit 40 processes the Doppler intermediate frequency signal in the differential signal form accessed by the Doppler differential output circuit 30 for frequency selective cancellation and outputs the Doppler intermediate frequency signal which has been processed by frequency selective cancellation. The frequency selective cancellation circuit 40 comprises the first equivalent resistance 401, the second equivalent resistance 402, and the equivalent capacitor 403. One end of the first equivalent resistance 401 is electrically connected to one end of the equivalent capacitor 403, and one end of the second equivalent resistance 402 is electrically connected to the other end of the equivalent capacitor 403. The other end of the first equivalent resistance 401 and the other end of the second equivalent resistance 402 serve as two input terminals 41, and the two ends of the equivalent capacitor 403 serve as two output terminals 42. The frequency selective cancellation circuit 40 is electrically connected to the Doppler differential output circuit 30 at the two input terminals 41, with the two poles of the Doppler intermediate frequency signal in the differential signal form accessed by the two input terminals 41, and the two output terminals 42 output the Doppler intermediate frequency signal after being processed by frequency selective cancellation.

Furthermore, in some embodiments of the present invention, in the step (C), based on mixer processing, the Doppler intermediate frequency signal corresponding to the frequency/phase difference between the local oscillator signal and the feedback signal is directly output in the form of differential signal. The corresponding Mixer circuit, which can directly output the differential signal form of the Doppler intermediate frequency signal based on mixer processing, is set with a frequency mixing circuit in the Doppler differential output circuit 30.

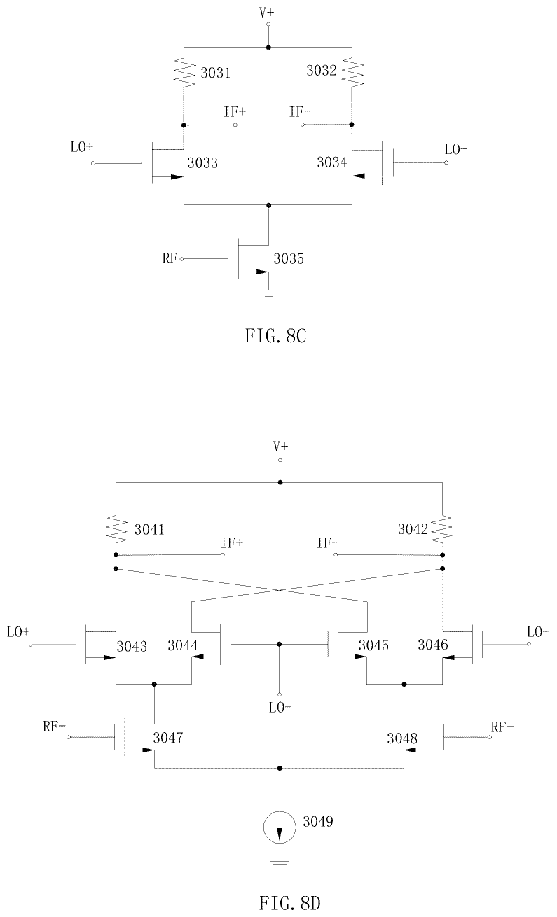

By way of example, as shown in FIGS. 8A to 8D of the drawings of the present invention, different circuit structures of the Doppler differential output circuit 30 are respectively illustrated.

Corresponding to FIG. 8A, the Doppler differential output circuit 30 comprises a first load 3011 and a second load 3012 formed in the form of equivalent resistance or equivalent inductance, a first MOS transistor 3013, and a second MOS transistor 3014. One end of the first load 3011 is electrically connected to one end of the second load 3012, and the other end of the first load 3011 is electrically connected to the drain of the first MOS transistor 3013. The other end of the second load 3012 is electrically connected to the drain of the second MOS transistor 3014. The source of the first MOS transistor 3013 is electrically connected to the source of the second MOS transistor 3014, so that the two ends of the interconnected first load 3011 and second load 3012 are connected to a power supply, and the two source electrodes of the interconnected first MOS transistor 3013 and second MOS transistor 3014 are configured to receive the feedback signal. The gate electrodes of the first MOS transistor 3013 and the second MOS transistor 3014 are configured to receive the inverted local oscillator signal, and the Doppler intermediate frequency signal in the form of differential signal is output from the drain of the first MOS transistor 3013 and the drain of the second MOS transistor 3014.

Corresponding to FIG. 8B, the Doppler differential output circuit 30 comprises a first MOS transistor 3021, a second MOS transistor 3022, a third MOS transistor 3023, and a fourth MOS transistor 3024. The drain of the first MOS transistor 3021 is electrically connected to the drain of the second MOS transistor 3022, and the drain of the third MOS transistor 3023 is electrically connected to the drain of the fourth MOS transistor 3024. The source of the first MOS transistor 3021 is electrically connected to the source of the third MOS transistor 3023, and the source of the second MOS transistor 3022 is electrically connected to the source of the fourth MOS transistor 3024. In this way, the feedback signals are connected in opposite phase between the two drains of the first MOS transistor 3021 and the second MOS transistor 3022, and between the two drains of the third MOS transistor 3023 and the fourth MOS transistor 3024 respectively. The four gates of the first MOS transistor 3021, the second MOS transistor 3022, the third MOS transistor 3023, and the fourth MOS transistor 3024 are input with the local oscillator signal in reverse phase, so that the Doppler intermediate frequency signals with differential signal form can be output between the two source electrodes of the first MOS transistor 3021 and the third MOS transistor 3023, and between the two source electrodes of the second MOS transistor 3022 and the fourth MOS transistor 3024.

Corresponding to FIG. 8C, the Doppler differential output circuit 30 comprises a first load 3031 and a second load 3032, a first MOS transistor 3033, a second MOS transistor 3034, and a third MOS transistor 3035, each of the first load 3031 and the second load 3032 is formed in the form of equivalent resistance or equivalent inductance. One end of the first load 3031 is electrically connected to one end of the second load 3032, and the other end of the first load 3031 is electrically connected to the drain of the first MOS transistor 3033. The other end of the second load 3032 is electrically connected to the drain of the second MOS transistor 3034. The source of the first MOS transistor 3033 and the source of the second MOS transistor 3034 are respectively electrically connected to the drain of the third MOS transistor 3035. The source of the third MOS transistor 3035 is grounded. In this way, the two ends of the interconnected first load 3031 and second load 3032 are connected to the power supply, the gate of the third MOS transistor 3035 is used to receive the feedback signal, and the gates of the first MOS transistor 3033 and the second MOS transistor 3034 are respectively used to receive the inverted local oscillator signal. The Doppler intermediate frequency signal in the differential signal form can be output from the drain of the first MOS transistor 3033 and the drain of the second MOS transistor 3034.

Corresponding to FIG. 8D, the Doppler differential output circuit 30 comprises a first load 3041 and a second load 3042 each formed in the form of equivalent resistance or equivalent inductance, a first MOS transistor 3043, a second MOS transistor 3044, a third MOS transistor 3045, a fourth MOS transistor 3046, a fifth MOS transistor 3047, a sixth MOS transistor 3048, and an electric current source 3049. One end of the first load 3041 is electrically connected to one end of the second load 3042, and the other end of the first load 3041 is respectively electrically connected to the drain of the first MOS transistor 3043 and the drain of the third MOS transistor 3045. The other end of the second load 3042 is respectively electrically connected to the drain of the second MOS transistor 3044 and the drain of the fourth MOS transistor 3046. The source of the first MOS transistor 3043 and the source of the second MOS transistor 3044 are electrically connected to the drain of the fifth MOS transistor 3047, and the source of the third MOS transistor 3045 and the source of the fourth MOS transistor 3046 are electrically connected to the drain of the sixth MOS transistor 3048. The source of the fifth MOS transistor 3047 and the source of the sixth MOS transistor 3048 are electrically connected to the electric current source 3049, so that the feedback signal in opposite phase is input to the gates of the fifth MOS transistor 3047 and the sixth MOS transistor 3048, and the local oscillator signal in opposite phase is input to the gates of the first MOS transistor 3043 and the second MOS transistor 3044, and the local oscillator signal in opposite phase is input to the gates of the third MOS transistor 3045 and the fourth MOS transistor 3046, wherein the local oscillator signal in same phase is input to the gate of the second MOS transistor 3044 and the gate of the third MOS transistor 3045. By connecting the power supply to the two ends of the interconnected first load 3041 and second load 3042, the Doppler intermediate frequency signal in differential signal form can be output at the other end of the first load 3041 and the other end of the second load 3042.

It can be understood that the structural principles of the different Doppler differential output circuits 30 mentioned above are only examples, and are applicable to the microwave detection device of the different embodiments mentioned above. The circuit structure of the Doppler differential output circuit 30 is diverse and cannot be listed one by one. It is not limited to the independent form of discrete components or integrated circuit forms, and can be implemented as a combination of discrete component form and integrated circuit form. The present invention does not limit this.

For example, in some embodiments of the present invention, the Doppler differential output circuit 30 and the oscillation unit 20 are integrated in a microwave chip in an integrated circuit form. In other embodiment of the present invention, the first equivalent resistance 401 and the second equivalent resistance 402 of the frequency selective cancellation circuit 40 are integrated into the microwave chip.

Particularly, in some embodiments of the present invention, the step (C) of the anti-interference microwave detection method comprises the following steps.

(C1) Mix the local oscillator signal and the feedback signal to extract a signal corresponding to the frequency/phase difference between the local oscillator signal and the feedback signal;

(C2) Use a reference ground of the antenna unit 10 to output a single-ended signal form of the Doppler intermediate frequency signal corresponding to the frequency/phase difference between the local oscillator signal and the feedback signal.

(C3) Inversely output the corresponding frequency/phase difference signal between the local oscillator signal and the feedback signal through reversing the Doppler intermediate frequency signal of the single-ended signal form, so as to convert the Doppler intermediate frequency signal of the single-ended signal form into the Doppler intermediate frequency signal in the differential signal form.

It is worth mentioning that in the step (C2), since only a single signal corresponding to the frequency/phase difference between the local oscillator signal and the feedback signal is extracted, the initial strength of the Doppler intermediate frequency signal in the single-ended signal output in the step (C2) can be ensured, which is beneficial for ensuring the initial strength of the Doppler intermediate frequency signal in the differential signal form output in the step (C3), and correspondingly is beneficial for ensuring the feedback accuracy of the detection of the motion of objects in the corresponding detection space based on the differential signal output in the step (D) by a frequency selective cancellation.

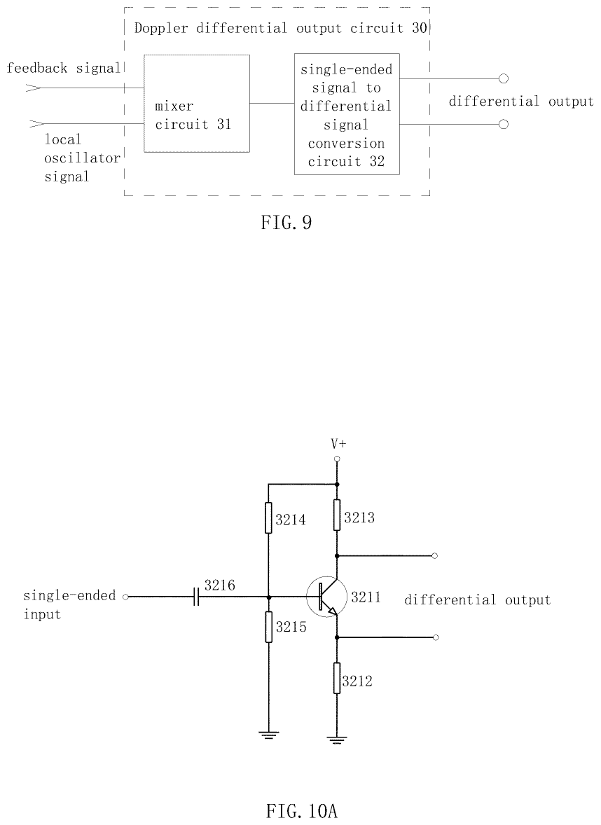

Correspondingly, referring to FIG. 9 of the drawings of the present invention, a circuit structure principle of the Doppler differential output circuit 30 is schematically illustrated. The Doppler differential output circuit 30 comprises a mixer circuit 31 and a single-ended signal to differential signal conversion circuit 32. The mixer circuit 31 is electrically connected to the antenna unit 10 and the oscillation unit 20 to receive the feedback signal and the local oscillator signal, and output the corresponding Doppler intermediate frequency signal in a single-ended signal form by mixing and detecting the frequency/phase difference between the feedback signal and the local oscillator signal. The single-ended to differential signal conversion circuit 32 is electrically connected to the mixer circuit 31 to receive the single-ended Doppler intermediate frequency signal and converts it to a differential signal form by inverting the single-ended signal form.

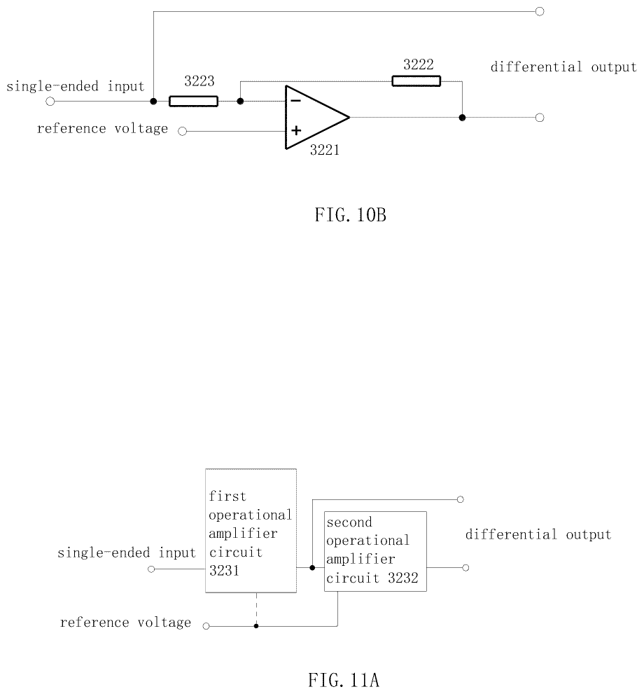

By way of example, referring to FIG. 10A and FIG. 10B of the drawings of the present invention, different basic circuit structures of the single-ended to differential signal conversion circuit 32 based on a type of structural principle of the single-ended to differential signal conversion circuit 32 are illustrated.

Corresponding to FIG. 10A, the single-ended signal to differential signal conversion circuit 32 comprises a transistor 3211, a first resistor 3212, a second resistor 323123, a third resistor 3214, a fourth resistor 3215, and a capacitor 3216. The emitter of the transistor 3211 is grounded through the first resistor 322, the collector of the transistor 3211 is connected to the power supply through the second resistor 323123, the base of the transistor 3211 is connected to the power supply through the third resistor 3214, grounded through the fourth resistor 3215, and accessed to the Doppler intermediate frequency signal in the single-ended signal form by the capacitor 3216, and the Doppler intermediate frequency signal in the differential signal form is formed between the collector and emitter of the transistor 3211.

Corresponding to FIG. 10B, the single-ended to differential signal conversion circuit 32 comprises an operational amplifier 3221, a first resistor 3222, and a second resistor 3223. The operational amplifier 3221 is connected to the reference voltage at the inverting input terminal and connected to the output terminal of the operational amplifier 3221 through the first resistor 3222, and is connected to the Doppler intermediate frequency signal in the single-ended signal form through the second resistor 3223. Thus, the differential signal form of the Doppler intermediate frequency signal is output between one end of the second resistor 3223 which have access to the Doppler intermediate frequency signal in the single-ended signal form and the output terminal of the operational amplifier 3221.

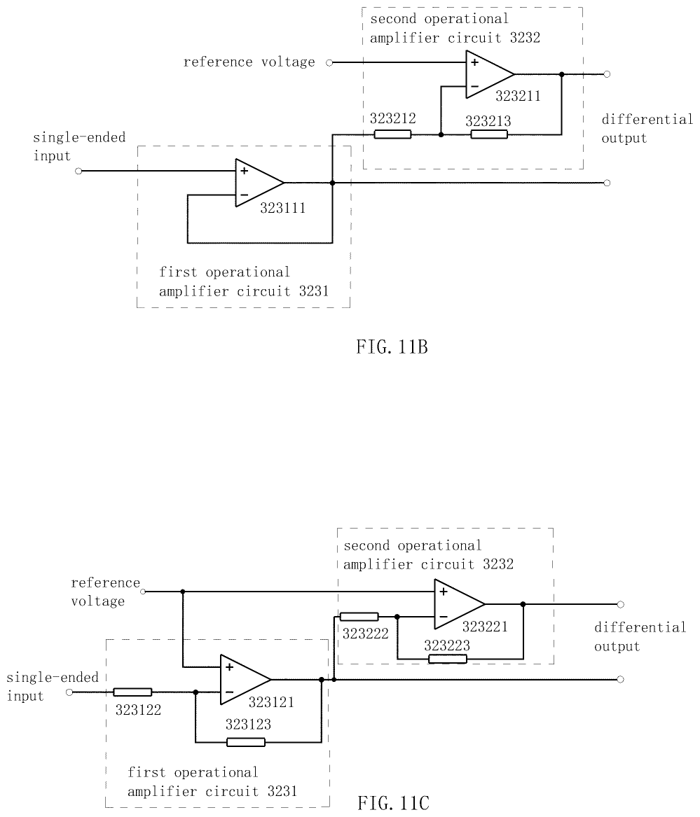

By way of example, referring to FIGS. 11A to 11D of the drawings of the present invention, a structural principle and corresponding different basic circuit structures of the single-ended signal to differential signal conversion circuit 32 are respectively illustrated. The single-ended to differential signal conversion circuit 32 comprises a first operational amplifier circuit 3231 and a second operational amplifier circuit 3232. The first operational amplifier circuit 3231 receives a single-ended Doppler intermediate frequency signal, and its output terminal is electrically connected to the input terminal of the second operational amplifier circuit 3232. The Doppler intermediate frequency signal in differential signal form is output between the output terminal of the first operational amplifier circuit 3231 and the output terminal of the second operational amplifier circuit 3232.

Corresponding to FIG. 11B, the first operational amplifier circuit 3231 comprises a first operational amplifier 323111, and the same phase input terminal of the first operational amplifier 323111 is an input terminal of the circuit for receiving the single-ended Doppler intermediate frequency signal, and the output terminal of the first operational amplifier 323111 functions as an output terminal of the circuit. The second operational amplifier circuit 3232 comprises a second operational amplifier 323211, a first resistor 323212, and a second resistor 323213. The input terminal of the circuit is the inverting input terminal of the second operational amplifier 323211, and the output terminal is the output terminal of the second operational amplifier 323211. The second operational amplifier 323211 is connected to the reference voltage at the same phase input terminal, and is electrically connected to the output terminal of the second operational amplifier 323211 through the second resistor 323213 at the inverting input terminal. The output terminal of the first operational amplifier 323111 is electrically connected to the inverting input terminal of the second operational amplifier 323211 through the first resistor 323212. The inverting input terminal of the first operational amplifier 323111 is electrically connected to the output terminal of the second operational amplifier 323211, so that the Doppler intermediate frequency signal in the differential signal form is output between the output terminals of the first operational amplifier 323111 and the second operational amplifier 323211.

Corresponding to FIG. 11C, the first operational amplifier circuit 3231 comprises the first operational amplifier 323121, the first resistor 323122, and the second resistor 323123, wherein the inverting input terminal of the first operational amplifier 323121 is used as an input terminal for receiving the single-ended Doppler intermediate frequency signal in single-ended signal form, the output terminal of the first operational amplifier 323121 is used as the output terminal of the circuit. The inverting input terminal of the first operational amplifier 323121 receives the Doppler intermediate frequency signal in single-ended signal form through the first resistor 323122, and the reference voltage is input to the non-inverting input terminal. The inverting input terminal and the output terminal of the first operational amplifier 323121 are electrically connected through the second resistor 323123. The second operational amplifier circuit 3232 comprises the second operational amplifier 323221, the third resistor 323222, and the fourth resistor 323223. The inverting input terminal of the second operational amplifier 323221 is used as the input terminal, and the output terminal of the second operational amplifier 323221 is used as the output terminal. The output terminal of the first operational amplifier 323121 is electrically connected to the inverting input terminal of the second operational amplifier 323221 through the third resistor 323222. The inverting input terminal and the output terminal of the second operational amplifier 323221 are electrically connected through the fourth resistor 323223. Thus, the Doppler intermediate frequency signal in the differential signal form is output between the output terminals of the first operational amplifier 323121 and the second operational amplifier 323221.

Corresponding to FIG. 11D, the first operational amplifier circuit 3231 comprises a first operational amplifier 323131, a first resistor 323132, a second resistor 323133 second resistor 323123, a first capacitor 323134, a second capacitor 323135, and a third capacitor 323136. The inverting input terminal of the first operational amplifier 323131 is used as the input terminal for receiving the Doppler intermediate frequency signal in the single-ended signal form. The output terminal of the first operational amplifier 323131 is used as the output terminal. The first operational amplifier 323131 is electrically connected to the output terminal through the third capacitor 323136 from its inverting input terminal, and sequentially connected to the output terminal through the first resistor 323132 and the second resistor 323133 second resistor 323123, and then connected to the Doppler intermediate frequency signal in the single-ended signal form through the first resistor 323132 and the first capacitor 323134, and finally grounded through the second capacitor 323135. The second operational amplifier circuit 3232 comprises a second operational amplifier 323231, a third resistor 323232, and a fourth resistor 323233. The inverting input terminal of the second operational amplifier 323231 is used as the input terminal, and the output terminal of the second operational amplifier 323231 is used as the output terminal of the circuit. The inverting input terminal of the second operational amplifier 323231 is electrically connected to the output terminal of the first operational amplifier 323131 through the third resistor 323232, and the inverting input terminal and the output terminal of the second operational amplifier 323231 are electrically connected through the fourth resistor 323233. In this way, the Doppler intermediate frequency signal in the differential signal form is output between the output terminals of the first operational amplifier 323131 and the second operational amplifier 323231.

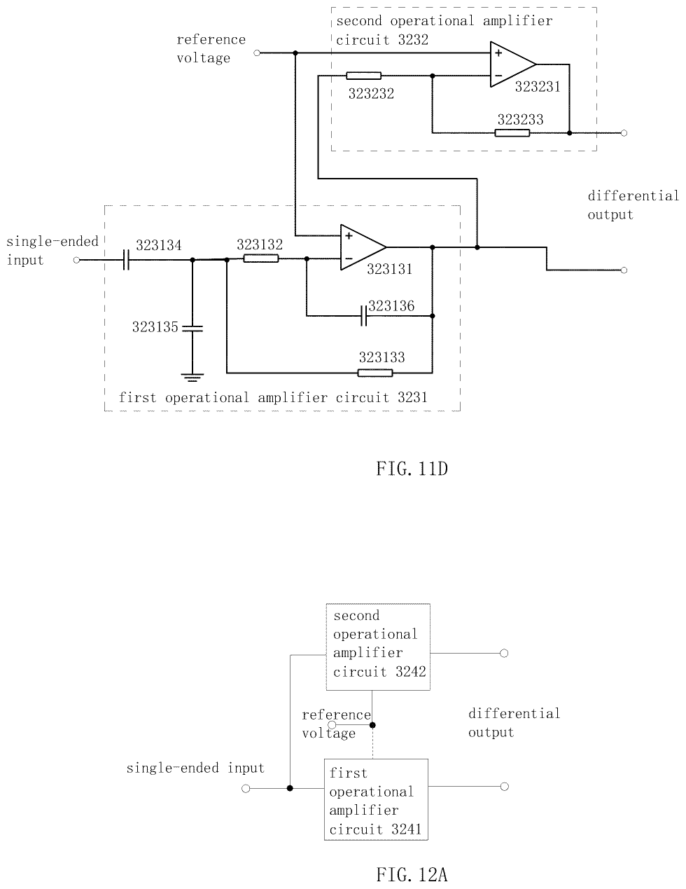

Further by way of example, referring to FIGS. 12A to 12C of the drawings of the present invention, different basic circuit structures based on another structural principle of the single-ended to differential signal conversion circuit 32 is schematically illustrated. The single-ended to differential signal conversion circuit 32 comprises a first operational amplifier circuit 3241 and a second operational amplifier circuit 3242, wherein the input terminal of the first operational amplifier circuit 3241 is electrically connected to the input terminal of the second operational amplifier circuit 3242, so as to receive the Doppler intermediate frequency signal in the single-ended signal form and to output the Doppler intermediate frequency signal in the differential signal form between the output terminal of the first operational amplifier circuit 3241 and the output terminal of the second operational amplifier circuit 3242.

Corresponding to FIG. 12B, the first operational amplifier circuit 3241 comprises a first operational amplifier 324111, a first resistor 324112, a second resistor 3234113, and a first capacitor 324114. The single-ended Doppler intermediate frequency signal is input to the non-inverting input terminal of the first operational amplifier 324111 which functions as the input terminal, the output terminal of the first operational amplifier 324111 is used as the output terminal, and the first operational amplifier 324111 is electrically connected to its output terminal through the first resistor 324112 from its inverting input terminal, and sequentially grounded through the second resistor 323123 and the first capacitor 324114. The second operational amplifier circuit 3242 comprises a second operational amplifier 324211, a third resistor 324212, and a fourth resistor 324213. The inverting input terminal of the second operational amplifier 324211 is used as the input terminal, and the output terminal of the second operational amplifier 324211 is used as the output terminal. The non-inverting input terminal of the first operational amplifier 324111 is electrically connected to the inverting input terminal of the second operational amplifier 324211 through the third resistor 324212. The inverting input terminal and the output terminal of the second operational amplifier 324211 are electrically connected through the fourth resistor 324213. The non-inverting input terminal of the second operational amplifier 324211 is connected to the reference voltage. In this way, the Doppler intermediate frequency signal in the differential signal form is output between the output terminals of the first operational amplifier 324111 and the second operational amplifier 324211.

Corresponding to FIG. 12C, the first operational amplifier circuit 3241 comprises a first operational amplifier 324121, a first resistor 324122, a second resistor 324123 second resistor 323123, a third resistor 324124, and a fourth resistor 324125. The single-ended Doppler intermediate frequency signal is input to the inverting input terminal of the first operational amplifier 324121 which functions as the input terminal, and the output terminal of the first operational amplifier 324121 is used as the output terminal. The inverting input terminal of the first operational amplifier 324121 is electrically connected to its output terminal through the fourth resistor 324125, and grounded through the third resistor 324124. The non-inverting input terminal of the first operational amplifier 324121 is arranged to receive the single-ended Doppler intermediate frequency signal through the first resistor 324122, and grounded through the second resistor 324123 second resistor 323123. The second operational amplifier circuit 3242 comprises a second operational amplifier 324221, a fifth resistor 324222, and a sixth resistor 324223. The inverting input terminal of the second operational amplifier 324221 is used as the input terminal, and the output terminal of the second operational amplifier 324221 is used as the output terminal. The non-inverting input terminal of the second operational amplifier 324221 is sequentially connected to the inverting input terminal of the second operational amplifier 324221 through the first resistor 324122 and the fifth resistor 324222. The inverting input terminal and the output terminal of the second operational amplifier 324221 are electrically connected through the sixth resistor 324223. The second operational amplifier 324221 is connected to the reference voltage at the non-inverting input terminal, so that the Doppler intermediate frequency signal in the differential signal form is output between the output terminals of the first operational amplifier 324121 and the second operational amplifier 324221.

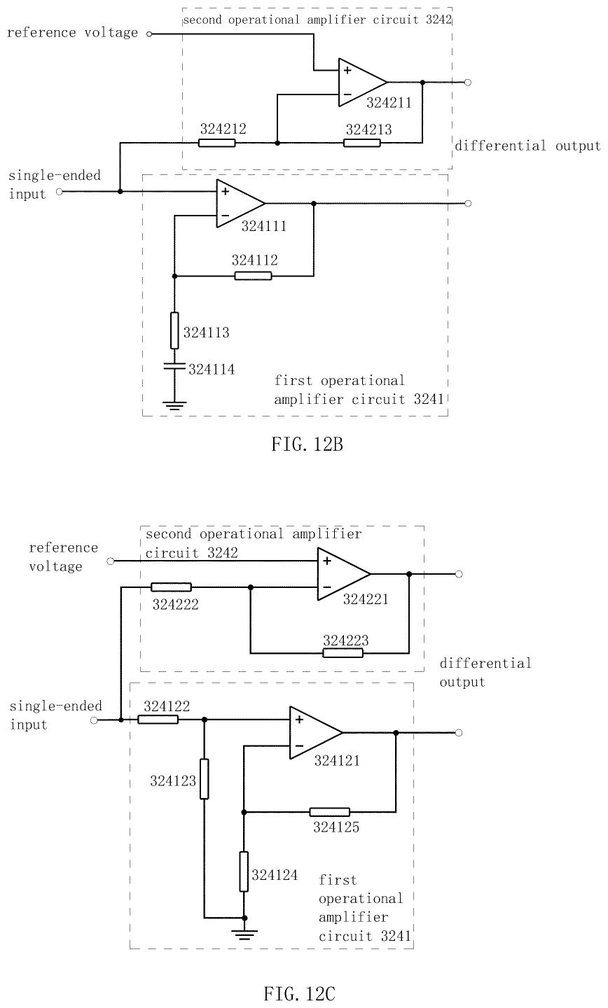

In a further example, referring to FIGS. 13A and 13B of the specification of the present invention, different basic circuit structures of the single-ended to differential signal conversion circuit 32 based on another structural principle are illustrated.

Corresponding to FIG. 13A, the single-ended to differential signal conversion circuit 32 comprises a first operational amplifier 3251, a second operational amplifier 3252, a first resistor 3253, a second resistor 3254, a third resistor 3255, and a fourth resistor 3256. The first operational amplifier 3251 is accessing a reference voltage at its non-inverting input terminal, and the single-ended Doppler intermediate frequency signal is input through the first resistor 3253 at the inverting input terminal of first operational amplifier 3251. The output terminal of the first operational amplifier 3251 is connected in sequence to the third resistor 3255 and the fourth resistor 3256, and then connected to the output terminal of the second operational amplifier 3252. The inverting input terminal and the output terminal of the first operational amplifier 3251 are connected through the second resistor 3254. The inverting input terminal and the output terminal of the second operational amplifier 3252 are connected through the fourth resistor 3256. The inverting input terminal of the first operational amplifier 3251 is electrically connected to the non-inverting input terminal of the second operational amplifier 3252, so as to output the Doppler intermediate frequency signal in the differential signal form between the output terminals of the first operational amplifier 3251 and the second operational amplifier 3252.

Corresponding to FIG. 13B, the single-ended to differential signal conversion circuit 32 comprises the first operational amplifier 3261, the second operational amplifier 3262, the first resistor 3263, the second resistor 3264, the third resistor 3265, and the fourth resistor 3266. The first operational amplifier 3261 is accessing the reference voltage at its non-inverting input terminal and is electrically connected to the inverting input terminal of the second operational amplifier 3262 at its inverting input terminal. The output terminal of the first operational amplifier 3261 is electrically connected to the non-inverting input terminal of the second operational amplifier 3262 via the fourth resistor 3266. The inverting input terminal and the output terminal of the first operational amplifier 3261 are electrically connected via the third resistor 3265. The second operational amplifier 3262 is receiving the Doppler intermediate frequency signal in the single-ended signal form at its non-inverting input terminal through the first resistor 3263. The inverting input terminal and the output terminal of the second operational amplifier 3262 are electrically connected via the second resistor 3264. Thus, the Doppler intermediate frequency signal in the differential signal form is output between the output terminals of the first operational amplifier 3261 and the second operational amplifier 3262.

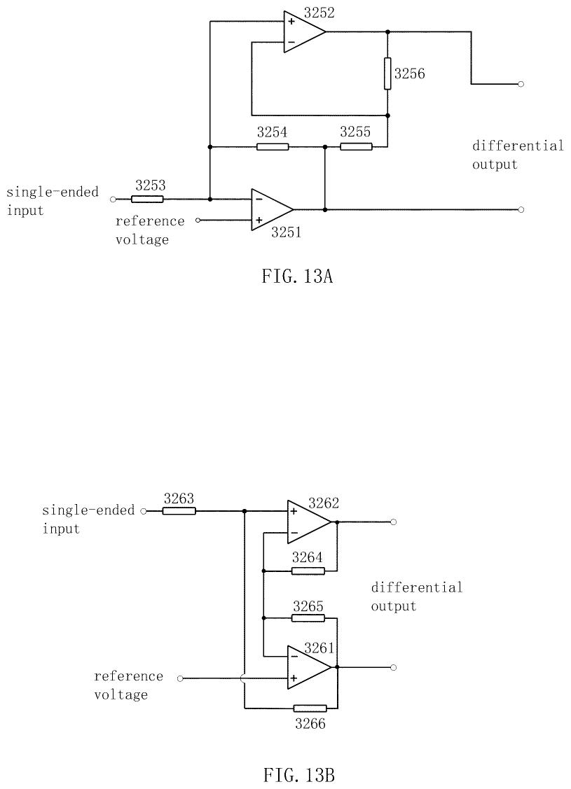

It is also understood that the structure of the aforementioned single-ended to differential signal conversion circuit 32 is only an example, and the corresponding Doppler differential output circuit 30 is applicable to the microwave detection device of the aforementioned different embodiments. For example, corresponding to FIG. 14A, the partial circuit structure of the single-ended to differential signal conversion circuit 32 shown in FIG. 11D is used in FIG. 6A. Corresponding to FIG. 14B, the partial circuit structure of the single-ended to differential signal conversion circuit 32 shown in FIG. 13A is used in FIG. 6A.

It is worth mentioning that the circuit structure of the single-ended to differential signal conversion circuit 32 is diverse and cannot be listed one by one. Its main structural feature is the use of a single-ended input and a differential output structure. By inverting the Doppler intermediate frequency signal of the single-ended signal form input and converting the input single-ended signal form Doppler intermediate frequency signal into an inverted signal, the conversion from the single-ended signal form Doppler intermediate frequency signal to the differential signal form of Doppler intermediate frequency signal is formed. It is not limited to the independent form of discrete components or integrated circuit forms, and can be implemented as a combination of discrete component form and integrated circuit form. The present invention is not limited to this.

For example, in some embodiments of the present invention, the Doppler differential output circuit 30 is used. The oscillation unit 20 and the Doppler differential output circuit 30 are integrated and integrated in a microwave chip in the form of an integrated circuit. In some other embodiments of the present invention, the first equivalent resistance 401 and the second equivalent resistance 402 of the frequency selective cancellation circuit 40 are integrated in the same microwave chip.

For example, in some embodiments of the present invention, the oscillation unit 20 and the mixer circuit 31 of the Doppler differential output circuit 30 are integrated and integrated into a microwave chip in the form of an integrated circuit, while the single-ended to differential signal conversion circuit 32 of the Doppler differential output circuit 30 is external to the microwave chip.

For example, in some embodiments of the present invention, The oscillation unit 20 and the corresponding first operational amplifier circuit shown in FIG. 11A to FIG. 12C or the corresponding first operational amplifier shown in FIG. 13A and FIG. 13B of the single-ended to differential signal conversion circuit 32 are integrated and formed in a microwave chip, while the corresponding second operational amplifier circuit shown in FIG. 11A to FIG. 12C or the corresponding second operational amplifier shown in FIG. 13A and FIG. 13B of the single-ended to differential signal conversion circuit 32 are external to the microwave chip, wherein the mixer circuit 31 of the Doppler differential output circuit 30 is external to the microwave chip or integrated into the microwave chip to form a microwave chip that outputs Doppler intermediate frequency signals in the single-ended signal format.

Particularly, in some embodiments of the present invention, the anti-interference microwave detection method further comprises a following step.

(E) Perform differential amplification processing on the Doppler intermediate frequency signal in the differential signal form.

Understandably, the step (E) is executed between the step (C) and the step (D), and/or after the step (D), the present invention is not limited thereto.

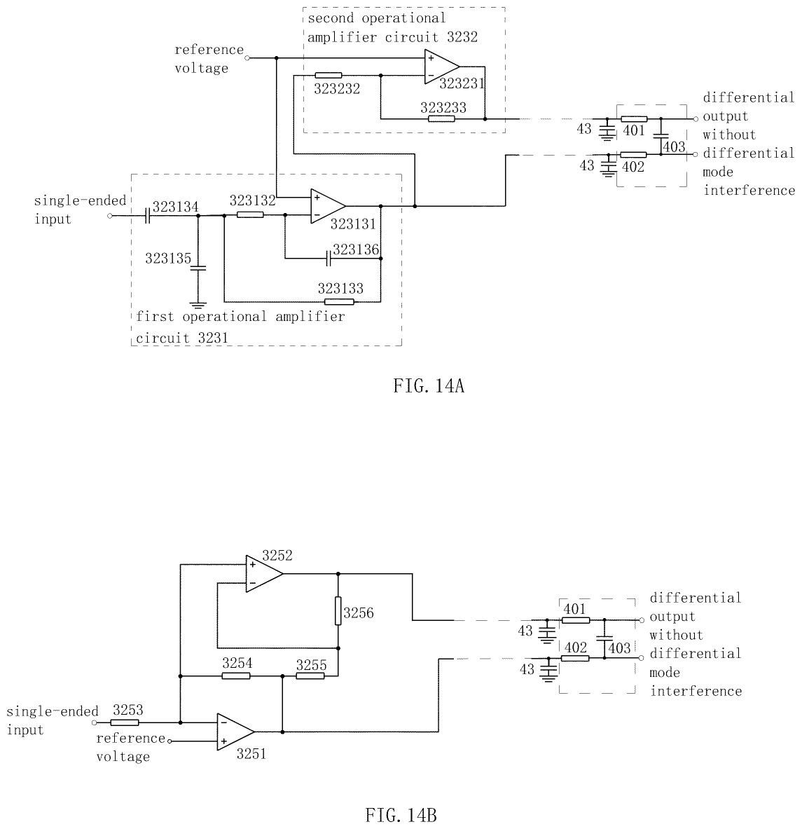

Correspondingly, referring to FIGS. 15A and 15B of the drawings of the present invention, the microwave detection device further comprises at least one differential amplifier circuit 50, wherein the differential amplifier circuit 50 is set between the Doppler differential output circuit 30 and the frequency selective cancellation circuit 40, and/or is set at the two output terminals 42 of the frequency selective cancellation circuit 40, so as to differentially amplify the Doppler intermediate frequency signal in the differential signal form output from the Doppler differential output circuit 30 using the differential amplifier circuit, and/or differentially amplify the Doppler intermediate frequency signal in the differential signal form output from the two output terminals 42 of the frequency selective cancellation circuit 40t, and based on the common mode suppression characteristics of the differential amplification process of the Doppler intermediate frequency signal in the differential signal form, amplifies the Doppler intermediate frequency signal in the differential signal form while suppressing the first type of interference signal in the Doppler intermediate frequency signal in the differential signal form that is amplified.

It is worth mentioning that in the state where the differential amplifier circuit 50 is set between the Doppler differential output circuit 30 and the frequency selective cancellation circuit 40, when the two input terminals 41 of the frequency selective cancellation circuit 40 are electrically connected with the ground capacitor 43, the corresponding ground capacitor 43 can be electrically connected to the corresponding input terminal 41 of the frequency selective cancellation circuit 40 in a state where it is set between the differential amplifier circuit 50 and the Doppler differential output circuit 30, or it can be set between the differential amplifier circuit 50 and the frequency selective cancellation circuit 40 and electrically connected to the corresponding input terminal 41.

In addition, it is also worth mentioning that based on the demand for multi-stage selective frequency cancellation processing, in some embodiments of the present invention, when the number of frequency selective cancellation circuits 40 is multiple and corresponds to a series structure as shown in FIG. 7A, the differential amplifier circuit 50 is further set between the two frequency selective cancellation circuits 40 that are connected in series, so as to form isolation between the two frequency selective cancellation circuits 40 that are connected in series based on the setting of the differential amplifier circuit 50 between them, and ensure the independence of the two frequency selective cancellation circuits 40 that are connected in series, so that the differential signal cancellation processes of the two frequency selective cancellation circuits 40 that are connected in series for the corresponding frequency bands do not affect each other, so as to ensure the multi-stage selective frequency cancellation effect.

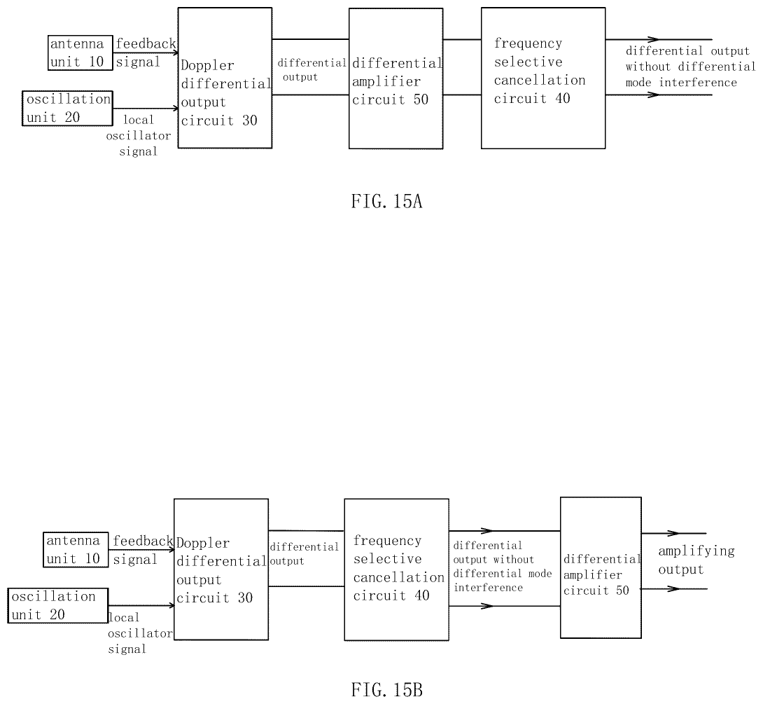

To further describe the present invention, referring to FIG. 16 of the drawings of the present invention, the structural principle of the differential amplifier circuit 50 is schematically shown. It can be understood that based on the selection of the power supply mode (dual power supply or single power supply) of the differential amplifier circuit 50 and the corresponding parameter and optimized design, the circuit structure of the differential amplifier circuit 50 is diverse and cannot be listed one by one. It is not limited to the independent form of discrete components or integrated circuit form, and it can also be implemented as a combination of discrete component form and integrated circuit form. The main structural feature of the differential amplifier circuit 50 is the use of double-ended input and double-ended output. The Doppler intermediate frequency signal in differential signal form is input between the base and ground of the two transistors, and the differential amplified Doppler intermediate frequency signal in differential signal form is output between the collectors of the two transistors.

Furthermore, in some embodiments of the present invention, the anti-interference microwave detection method further comprises a step (F) of converting the Doppler intermediate frequency signal from the differential signal form to the single-ended signal form. It can be understood that when the anti-interference microwave detection method comprises the step (E) after the step (D), the step (F) is performed after the step (E).

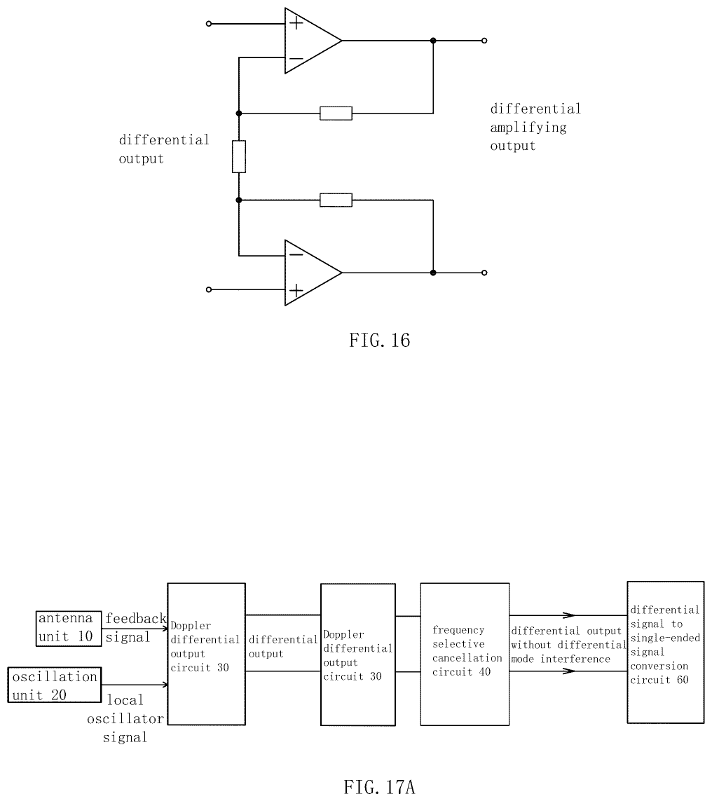

Correspondingly, referring to FIGS. 17A and 17B of the drawings of the present invention, the microwave detection device further comprises a differential signal to single-ended signal conversion circuit 60, wherein the differential signal to single-ended signal conversion circuit 60 is configured to receive and access the Doppler intermediate frequency signal in the differential signal form after being processed by the frequency selective cancellation, and corresponding to the step (F), the converted differential signal form of the Doppler intermediate frequency signal is output in the single-ended signal form with the reference ground of the antenna unit 10 as the ground. This process suppresses and eliminates common mode interference during the conversion from the differential signal form to single-ended signal form of the Doppler intermediate frequency signal, thereby suppressing and eliminating the first type of interference signal in the Doppler intermediate frequency signal output in the single-ended signal form.

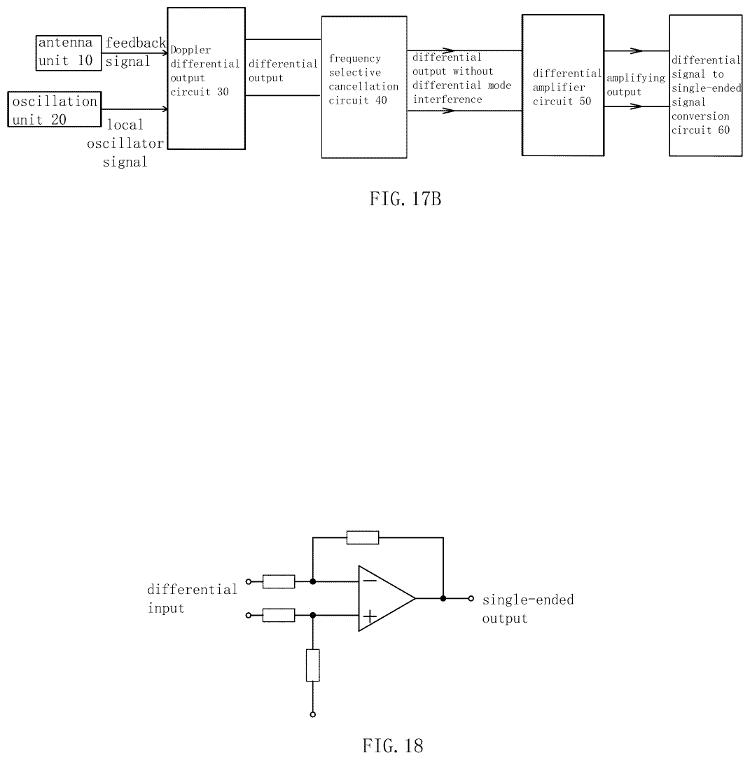

In order to further describe the present invention, referring to FIG. 18 of the drawings of the present invention, the structural principle of the differential signal to single-ended signal conversion circuit 60 is illustrated, wherein the Doppler intermediate frequency signal is converted from the differential signal form to the single-ended signal form based on the operational amplifier which implements the opposite phase superposition of the Doppler intermediate frequency signal in the differential signal form. During the conversion process, the common mode interference is suppressed and eliminated due to mutual cancellation in the superposition process of the differential signal form of the Doppler intermediate frequency signal, which corresponds to the suppression and elimination of the first type of interference signal in the Doppler intermediate frequency signal output in the single-ended signal form.

It can also be understood that, based on the above structural principles, the circuit structure of the differential signal to single-ended signal conversion circuit 60 for converting the differential signal to the single-ended signal can be diverse and cannot be listed one by one, depending on the choice of power supply mode (dual power supply or single power supply) for the circuit and the corresponding parameter and optimized design. It is not limited to the independent form of discrete component or integrated circuit form, and can also be implemented as a combination of discrete component form and integrated circuit form, which is not limited by the present invention.

Alternatively, in some embodiments of the present invention, by performing A/D conversion on the two poles of the Doppler intermediate frequency signal in the differential signal form, the suppression and elimination of common mode interference can be achieved in the subsequent data-based quantification identification and operation, which is equivalent to achieving the elimination of the common mode interference purpose of converting the Doppler intermediate frequency signal in the differential signal form into the single-ended signal form.

It is worth mentioning that by forming the Doppler intermediate frequency signal in the differential signal form, the external radiation of the Doppler intermediate frequency signal in the differential signal form can cancel each other out, and the interference of the Doppler intermediate frequency signal on the environment and the corresponding circuit can be suppressed, which is conducive to improve the anti-interference ability of the microwave detection device. In addition, the use of capacitor components in the transmission path of the Doppler intermediate frequency signal can be greatly reduced or even avoided by differential amplification and/or conversion to the Doppler intermediate frequency signal in the single-ended signal form, which is advantageous for ensuring the immediacy of the Doppler intermediate frequency signal and realizing real-time detection of human actions such as human breathing and heartbeat.

It can be understood that the structural principle of the differential signal to single-ended signal conversion circuit 60 of the microwave detection device is only an example. Based on the frequency selective cancellation circuit 40, the microwave detection device accurately eliminates the second type of interference signal in the corresponding frequency range of the Doppler intermediate frequency signal in a selective frequency cancellation manner. The feedback accuracy of the Doppler intermediate frequency signal of the differential signal output by the frequency selective cancellation circuit 40 to the detection of the motions of objects in the corresponding detection space can be guaranteed. Therefore, it is possible to eliminate the step of data-based quantification identification and operation of the single-ended signal generated between any pole and the reference ground in the step of differential signal to single-ended signal conversion step for the Doppler intermediate frequency signal in the differential signal output by the frequency selective cancellation circuit 40, and can still obtain accurate and stable detection results for human activities comprising movement, micro-movement, breathing, and heartbeat.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and are subject to change without departure from such principles. Therefore, this invention includes all modifications encompassed within the spirit and scope of the following claims.

What is claimed is:

1. An interference-resistant microwave detection method, comprising the following steps:
(A) emitting a detection beam corresponding to a local oscillator signal to form a corresponding detection space;
(B) receiving an echo formed by the detection beam which is reflected by a detected object in the detection space and generating a feedback signal;
(C) outputting a Doppler intermediate frequency signal in a differential signal form, wherein the Doppler intermediate frequency signal corresponds to the frequency/phase difference between the local oscillator signal and the feedback signal; and
(D) outputting the Doppler intermediate frequency signal which has been processed by frequency selective cancellation, wherein a common-mode interference, generated by a wireless communication signal in an environment interference signal superimposed on the feedback signal, is capable of being eliminated in the Doppler intermediate frequency signal, wherein the wireless communication signal has any frequency relationship selected from the group consisting of same frequency, adjacent frequency and harmonic frequency with a frequency of the local oscillator signal.

2. The interference-resistant microwave detection method of claim 1, wherein in the step (D), a frequency selective cancellation circuit is used to perform the selective frequency cancellation on the Doppler intermediate frequency signal in the differential form output in the step (C), wherein the frequency selective cancellation circuit comprises a first equivalent resistance, a second equivalent resistance, and an equivalent capacitor, wherein one end of the first equivalent resistance is electrically connected to one end of the equivalent capacitor, and one end of the second equivalent resistance is electrically connected to the other end of the equivalent capacitor, wherein the other ends of the first and second equivalent resistances correspond to two input terminals of the frequency selective cancellation circuit, and two ends of the equivalent capacitor correspond to two output terminals of the frequency selective cancellation circuit, wherein the Doppler intermediate frequency signal in the differential form output in the step (C) is input from the two input terminals, and the Doppler intermediate frequency signal processed by the selective frequency cancellation is output from the two output terminals.

3. The interference-resistant microwave detection method of claim 2, wherein the first equivalent resistance and the second equivalent resistance are set to have a resistance value of approximately 39 kΩ within an error range of 25%, and the equivalent capacitor is set to have a capacitance of approximately 47 nF in an error range of 25%.

4. The interference-resistant microwave detection method of claim 2, wherein the equivalent capacitor is set in series with two capacitors, wherein the frequency selective cancellation circuit is grounded between the two series-connected capacitors.

5. The interference-resistant microwave detection method of claim 2, wherein each of the two input terminals of the frequency selective cancellation circuit is electrically connected to a ground capacitor.

6. The interference-resistant microwave detection method of claim 1, wherein between the step (C) and the step (D), and/or after the step (D), the anti-interference microwave detection method further comprises a step (E) of differentially amplifying the Doppler intermediate frequency signal in the differential form.

7. The interference-resistant microwave detection method of claim 6, wherein after the step (D), the anti-interference microwave detection method further comprises a step (F) of converting the Doppler intermediate frequency signal from the differential signal form to a single-ended signal form.

8. The interference-resistant microwave detection method of claim 1, wherein in the step (C), the Doppler intermediate frequency signal in the differential signal form corresponding to the frequency/phase difference between the local oscillator signal and the feedback signal is directly output in a frequency mixing process.

9. The interference-resistant microwave detection method of claim 1, wherein the step (C) comprises the following steps:
(C1) mixing the local oscillator signal and the feedback signal in the frequency conversion process, so that the Doppler intermediate frequency signal corresponding to the frequency/phase difference between the local oscillator signal and the feedback signal is extracted;
(C2) outputting the Doppler intermediate frequency signal in a single-ended signal form corresponding to the frequency/phase difference between the local oscillator signal and the feedback signal; and
(C3) by inversely outputting the Doppler intermediate frequency signal in the single-ended signal form corresponding to the frequency/phase difference signal between the local oscillator signal and the feedback signal in an inverted manner, converting the Doppler intermediate frequency signal from the single-ended signal form to the differential signal form.

10. A microwave detection device, comprising:
an oscillation unit which is configured for generating a local oscillator signal;
an antenna unit which is fed and connected to the oscillation unit to emit a corresponding detection beam corresponding to a frequency of the local oscillator signal to form a corresponding detection space, and to receive an echo formed by the detection beam which is reflected by a detected object in the detection space, so as to generate a feedback signal;
a Doppler differential output circuit which is electrically connected to the antenna unit and the oscillation unit to output a Doppler intermediate frequency signal in a differential signal form, wherein the Doppler intermediate frequency signal corresponds to the frequency/phase difference between the local oscillator signal and the feedback signal; and
at least a frequency selective cancellation circuit which is electrically connected to the Doppler differential output circuit for eliminating a predetermined frequency range in the Doppler intermediate frequency signal in the differential signal form through frequency selective cancellation, so as to eliminate the common-mode interference in the Doppler intermediate frequency signal, which is caused by a wireless communication signal with any predetermined frequency relationship with a frequency of the local oscillator signal, in the environment interference signal superimposed on the feedback signal in the differential signal form, wherein the predetermined frequency relationship is selected from the group consisting of same frequency, adjacent frequency, and harmonic frequency.

11. The microwave detection device of claim 10, wherein the frequency selective cancellation circuit comprises a first equivalent resistance, a second equivalent resistance, and an equivalent capacitor, wherein one end of the first equivalent resistance is electrically connected to one end of the equivalent capacitor, and one end of the second equivalent resistance is electrically connected to the other end of the equivalent capacitor, wherein the frequency selective cancellation circuit, which adopts the other end of the first equivalent resistance and the other end of the second equivalent resistance as two input terminals, and two ends of the equivalent capacitor as two output terminals, inputs the Doppler intermediate frequency signal in the differential signal form output by the Doppler differential output circuit from the two input terminals, and outputs the Doppler intermediate frequency signal that has been processed by the frequency selective cancellation from the two output terminals.

12. The microwave device of claim 11, wherein the first equivalent resistance and the second equivalent resistance are set to have a resistance value of approximately 39 kΩ within an error range of 25%, and the equivalent capacitor is set to have a capacitance of approximately 47 nF in an error range of 25%.

13. The microwave detection device of claim 11, wherein the equivalent capacitor is set in series with two capacitors, wherein the frequency selective cancellation circuit is grounded between the two series-connected capacitors.

14. The microwave detection device of claim 11, wherein each of the two input terminals of the frequency selective cancellation circuit is electrically connected to a ground capacitor.

15. The microwave detection device of claim 10, wherein the Doppler differential output circuit is configured to directly output the Doppler intermediate frequency signal in the differential signal form corresponding to the frequency/phase difference between the local oscillator signal and the feedback signal in a frequency mixing process.

16. The microwave detection device of claim 10, wherein the Doppler differential output circuit comprises a first load and a second load each formed in a form of equivalent resistance or equivalent inductance, a first MOS transistor, and a second MOS transistor, wherein one end of the first load is electrically connected to one end of the second load, and the other end of the first load is electrically connected to a drain of the first MOS transistor, wherein the other end of the second load is electrically connected to a drain of the second MOS transistor, wherein a source of the first MOS transistor is electrically connected to a source of the second MOS transistor, wherein two ends of the interconnected first load and second loads are connected to a power supply, and two sources of the interconnected first MOS transistor and second MOS transistor are arranged to receive the feedback signal, wherein gate electrodes of the first MOS transistor and the second MOS transistor are respectively arranged to receive an inverted local oscillator signal, wherein the Doppler intermediate frequency signal in the differential signal form is output from the drains of the first MOS transistor and the second MOS transistor.

17. The microwave detection device of claim 15, wherein the Doppler differential output circuit comprises a first MOS transistor, a second MOS transistor, a third MOS transistor, and a fourth MOS transistor, wherein a drain of the first MOS transistor is electrically connected to a drain of the second MOS transistor, and a drain of the third MOS transistor is electrically connected to a drain of the fourth MOS transistor, wherein a source of the first MOS transistor is electrically connected to a source of the third MOS transistor, and a source of the second MOS transistor is electrically connected to a source of the fourth MOS transistor, wherein the feedback signal in opposite phase is input between the two drains of the first MOS transistor and the second MOS transistor, and between the two drains of the third MOS transistor and the fourth MOS transistor respectively, wherein four gates of the first MOS transistor, the second MOS transistor, the third MOS transistor, and the fourth MOS transistor are input with the local oscillator signal in reverse phase, wherein the Doppler intermediate frequency signals in the differential signal form is capable of being output between the two sources of the first MOS transistor and the third MOS transistor, and between the two sources of the second MOS transistor and the fourth MOS transistor.

18. The microwave detection device of claim 15, wherein the Doppler differential output circuit comprises a first load and a second load each formed in the form of equivalent resistor or equivalent inductance, a first MOS transistor, a second MOS transistor, and a third MOS transistor, wherein one end of the first load is electrically connected to one end of the second load, and the other end of the first load is electrically connected to a drain of the first MOS transistor, wherein the other end of the second load is electrically connected to a drain of the second MOS transistor, wherein a source of the first MOS transistor and a source of the second MOS transistor are electrically connected to a drain of the third MOS transistor, wherein a source of the third MOS transistor is grounded, wherein two ends of the interconnected first load and second load are connected to a power supply, wherein a gate of the third MOS transistor is configured to receive the feedback signal, wherein gates of the first MOS transistor and the second MOS transistor are respectively input with inverted local oscillator signal, so that the Doppler intermediate frequency signal in the differential signal form is output from the drain of the first MOS transistor and the drain of the second MOS transistor.

19. The microwave detection device of claim 15, wherein the Doppler differential output circuit comprises a first load and a second load each formed in the form of equivalent resistance or equivalent inductance, a first MOS transistor, a second MOS transistor, a third MOS transistor, a fourth MOS transistor, a fifth MOS transistor, a sixth MOS transistor, and a current source, wherein one end of the first load is electrically connected to one end of the second load, and the other end of the first load is respectively electrically connected to a drain of the first MOS transistor and a drain of the third MOS transistor, wherein the other end of the second load is respectively electrically connected to a drain of the second MOS transistor and a drain of the fourth MOS transistor, wherein a source of the first MOS transistor and a source of the second MOS transistor are electrically connected to a drain of the fifth MOS transistor, wherein a source of the third MOS transistor and a source of the fourth MOS transistor are electrically connected to a drain of the sixth MOS transistor, wherein a source of the fifth MOS transistor and a source of the sixth MOS transistor are electrically connected to the current source, wherein the feedback signal in opposite phase is respectively input to gates of the fifth MOS transistor and the sixth MOS transistor, wherein the local oscillator signal in opposite phase is respectively input to gates of the first MOS transistor and the second MOS transistor, wherein the local oscillator signal in opposite phase is respectively input to gates of the third MOS transistor and the fourth MOS transistor, wherein the local oscillator signal in the same phase is input to gates of the second MOS transistor and the third MOS transistor, wherein two ends of the interconnected first load and second load are connected to a power supply, wherein the Doppler intermediate frequency signal in the differential signal form is output from the other end of the first load and the other end of the second load.

20. The microwave detection device of claim 10, wherein the Doppler differential output circuit comprises a mixer circuit and a single-ended signal to differential signal conversion circuit, wherein the mixer circuit is electrically connected to the antenna unit and the oscillation unit to access the feedback signal and the local oscillator signal, and outputs a corresponding single-ended signal form of the Doppler intermediate frequency signal in a mixing detection manner, which corresponds to the frequency/phase difference between the feedback signal and the local oscillator signal, wherein the single-ended signal to differential signal conversion circuit is electrically connected to the mixer circuit to access the single-ended signal form of the Doppler intermediate frequency signal, wherein by reversing the single-ended form of the Doppler intermediate frequency signal, the single-ended signal form of the Doppler intermediate frequency signal is converted into the differential signal form of the Doppler intermediate frequency signal.

21. The microwave detection device of claim 10, wherein the microwave detection device further comprises at least a differential amplifier circuit which is set between the Doppler differential output circuit and the frequency selective cancellation circuit to differentially amplify the Doppler intermediate frequency signal in the differential signal form output by the Doppler differential output circuit.

22. The microwave detection device of claim 10, wherein the microwave detection device further comprises at least a differential amplifier circuit, wherein the differential amplifier circuit is set at two output terminals of the frequency selective cancellation circuit to differentially amplify the Doppler intermediate frequency signal in the differential signal form which is output from the frequency selective cancellation circuit.

23. The microwave detection device of claim 10, wherein the microwave detection device further comprises a differential signal to single-ended signal conversion circuit which is used to access the Doppler intermediate frequency signal in the differential signal form after the frequency selective cancellation, and convert the differential signal form of the Doppler intermediate frequency signal into a single-ended signal form of the Doppler intermediate frequency signal for output.

24. A microwave detection device, comprising:
an oscillation unit which is configured for generating a local oscillator signal;
an antenna unit which is fed and connected to the oscillation unit to emit a corresponding detection beam corresponding to a frequency of the local oscillator signal to form a corresponding detection space, and to receive an echo formed by the detection beam which is reflected by a detected object in the detection space, so as to generate a feedback signal; and
a Doppler differential output circuit which is electrically connected to the antenna unit and the oscillation unit to output a Doppler intermediate frequency signal in a differential signal form, wherein the Doppler intermediate frequency signal corresponds to the frequency/phase difference between the local oscillator signal and the feedback signal.

25. The microwave detection device of claim 24, wherein the Doppler differential output circuit comprises a first load and a second load each formed in a form of equivalent resistance or equivalent inductance, a first MOS transistor, and a second MOS transistor, wherein one end of the first load is electrically connected to one end of the second load, and the other end of the first load is electrically connected to a drain of the first MOS transistor, wherein the other end of the second load is electrically connected to a drain of the second MOS transistor, wherein a source of the first MOS transistor is electrically connected to a source of the second MOS transistor, wherein two ends of the interconnected first load and second loads are connected to a power supply, and two sources of the interconnected first MOS transistor and second MOS transistor are arranged to receive the feedback signal, wherein gate electrodes of the first MOS transistor and the second MOS transistor are respectively arranged to receive an inverted local oscillator signal, wherein the Doppler intermediate frequency signal in the differential signal form is output from the drains of the first MOS transistor and the second MOS transistor.

26. The microwave detection device of claim 24, wherein the Doppler differential output circuit comprises a first MOS transistor, a second MOS transistor, a third MOS transistor, and a fourth MOS transistor, wherein a drain of the first MOS transistor is electrically connected to a drain of the second MOS transistor, and a drain of the third MOS transistor is electrically connected to a drain of the fourth MOS transistor, wherein a source of the first MOS transistor is electrically connected to a source of the third MOS transistor, and a source of the second MOS transistor is electrically connected to a source of the fourth MOS transistor, wherein the feedback signal in opposite phase is input between the two drains of the first MOS transistor and the second MOS transistor, and between the two drains of the third MOS transistor and the fourth MOS transistor respectively, wherein four gates of the first MOS transistor, the second MOS transistor, the third MOS transistor, and the fourth MOS transistor are input with the local oscillator signal in reverse phase, wherein the Doppler intermediate frequency signals in the differential signal form is capable of being output between the two sources of the first MOS transistor and the third MOS transistor, and between the two sources of the second MOS transistor and the fourth MOS transistor.

27. The microwave detection device of claim 24, wherein the Doppler differential output circuit comprises a first load and a second load each formed in the form of equivalent resistor or equivalent inductance, a first MOS transistor, a second MOS transistor, and a third MOS transistor, wherein one end of the first load is electrically connected to one end of the second load, and the other end of the first load is electrically connected to a drain of the first MOS transistor, wherein the other end of the second load is electrically connected to a drain of the second MOS transistor, wherein a source of the first MOS transistor and a source of the second MOS transistor are electrically connected to a drain of the third MOS transistor, wherein a source of the third MOS transistor is grounded, wherein two ends of the interconnected first load and second load are connected to a power supply, wherein a gate of the third MOS transistor is configured to receive the feedback signal, wherein gates of the first MOS transistor and the second MOS transistor are respectively input with inverted local oscillator signal, so that the Doppler intermediate frequency signal in the differential signal form is output from the drain of the first MOS transistor and the drain of the second MOS transistor.

28. The microwave detection device of claim 24, wherein the Doppler differential output circuit comprises a first load and a second load each formed in the form of equivalent resistance or equivalent inductance, a first MOS transistor, a second MOS transistor, a third MOS transistor, a fourth MOS transistor, a fifth MOS transistor, a sixth MOS transistor, and a current source, wherein one end of the first load is electrically connected to one end of the second load, and the other end of the first load is respectively electrically connected to a drain of the first MOS transistor and a drain of the third MOS transistor, wherein the other end of the second load is respectively electrically connected to a drain of the second MOS transistor and a drain of the fourth MOS transistor, wherein a source of the first MOS transistor and a source of the second MOS transistor are electrically connected to a drain of the fifth MOS transistor, wherein a source of the third MOS transistor and a source of the fourth MOS transistor are electrically connected to a drain of the sixth MOS transistor, wherein a source of the fifth MOS transistor and a source of the sixth MOS transistor are electrically connected to the current source, wherein the feedback signal in opposite phase is respectively input to gates of the fifth MOS transistor and the sixth MOS transistor, wherein the local oscillator signal in opposite phase is respectively input to gates of the first MOS transistor and the second MOS transistor, wherein the local oscillator signal in opposite phase is respectively input to gates of the third MOS transistor and the fourth MOS transistor, wherein the local oscillator signal in the same phase is input to gates of the second MOS transistor and the third MOS transistor, wherein two ends of the interconnected first load and second load are connected to a power supply, wherein the Doppler intermediate frequency signal in the differential signal form is output from the other end of the first load and the other end of the second load.
